(19) United States
(12) Patent Application Publication
(10) Pub. No.: US 2026/0229294 A1
(43) Pub. Date: Aug. 6, 2026

(54) NONVOLATILE MEMORY DEVICE AND STORAGE DEVICE CONTAINING NONVOLATILE MEMORY DEVICE

(71) Applicant: SAMSUNG ELECTRONICS CO., LTD., Suwon-si (KR)

(72) Inventors: Eunji KIM, Suwon-si (KR); Byongmo MOON, Suwon-si (KR); Seonghyeog CHOI, Suwon-si (KR); Youngdon CHOI, Suwon-si (KR); Junghwan CHOI, Suwon-si (KR)

(73) Assignee: SAMSUNG ELECTRONICS CO., LTD., Suwon-si (KR)

(21) Appl. No.: 19/443,488

(22) Filed: Jan. 8, 2026

(30) Foreign Application Priority Data
Jan. 31, 2025 (KR) 10-2025-0012783

(51) Int. Cl. G11C 16/32; G11C 16/08

(52) U.S. Cl. CPC G11C 16/32; G11C 16/08; G11C 2207/2254

(57) ABSTRACT

A nonvolatile memory device may include a plurality of memory dies configured to perform write training based on training data received through a first channel and perform data input/output through the first channel. A first memory die and a second memory die among the plurality of memory dies respectively include first and second pattern generators for respectively generating first and second pattern data, first and second comparators for comparing the training data respectively with the first and second pattern data to respectively generate first and second pass/fail values for the training data, first and second input/output circuits connected to the first channel and respectively including first and second termination resistors, and first and second control logics for respectively generating first and second enable signals for respectively instructing turning on the first and second termination resistors during the write training and data input/output.

### CROSS-REFERENCE TO RELATED APPLICATION

This application claims priority to and the benefit of Korean Patent Application No. 10-2025-0012783 filed with the Korean Patent Office on January 31, 2025, the entire contents of which are incorporated herein by reference.

### BACKGROUND

### Field

The present disclosure relates to a nonvolatile memory device and a storage device including the nonvolatile memory device.

### Description of the Related Art

The storage device may include nonvolatile memory and a controller that controls the nonvolatile memory. Because nonvolatile memory and controllers have different operational characteristics, initialization or training may be required during initial operation of the storage device or between the nonvolatile memory and the controller.

Write training is the process of adjusting voltage, timing, etc. so that the memory cells store data in the correct state during the data recording process. Problems such as interference between adjacent memory cells, overwriting, and write failure may be solved through write training. However, as the write training time becomes longer, data writing is delayed, reducing the I/O processing volume of the system that supports parallel tasks.

### SUMMARY

One embodiment provides a nonvolatile memory device and a storage device including the nonvolatile memory device capable of reducing a write training operation time.

According to one embodiment of the present disclosure for solving these technical challenges, nonvolatile memory device may include a plurality of memory dies configured to perform write training based on training data received through a first channel and perform data input/output through the first channel, a first memory die among the plurality of memory dies includes a first pattern generator for generating first pattern data, a first comparator for comparing the training data with the first pattern data to generate a first pass/fail value for the training data, a first input/output circuit connected to the first channel and including a first termination resistor, and a first control logic for generating a first enable signal for instructing turning on the first termination resistor during the write training and data input/output, and a second memory die among the plurality of memory dies includes a second pattern generator for generating second pattern data, a second comparator for comparing the training data with the second pattern data to generate a second pass/fail value for the training data, a second input/output circuit connected to the first channel and including a second termination resistor, and a second control logic for generating a second enable signal for instructing turning off the second termination resistor during the write training and the data input/output.

A storage device according to one embodiment may include a storage controller configured to output training data, a first logic unit number instructing the buffer chip broadcasting, and a buffer chip comprising a first write training module configured to generate first pattern data, receive the training data through a first channel based on the first logic unit number, compare the training data with the first pattern data, and generate a first pass/fail value for the training data, and a second write training module which configured to generate second pattern data, receive the training data through the first channel based on the first logic unit number, compare the training data with the second pattern data, and generate a second pass/fail value for the training data.

A storage device according to one embodiment may include a storage controller including a memory including a first logic unit number instructing buffer chip broadcasting, a second logic unit number instructing a plurality of memory dies included in a group die, a pattern generator configured to generate pattern data, and a delay circuit configured to delay the pattern data according to a delay value and outputting training data, a buffer chip configured to receive an address corresponding to the first logic unit number, an address corresponding to the second logic unit number, and the training data at substantially the same timing from the storage controller through a first channel, generate first pattern data, and delay the first pattern data according to a delay value, and output first training data, and a nonvolatile memory configured to receive an address corresponding to the second logic unit number and the first training data from the buffer chip through a second channel at substantially the same timing, and generate a pass/fail value based on the first training data.

### BRIEF DESCRIPTION OF THE DRAWINGS

FIG. 1 is a block diagram of a storage device according to an embodiment.

FIG. 2 is a block diagram of a memory die according to an embodiment.

FIG. 3 is a block diagram of a storage controller according to an embodiment.

FIG. 4 is block information according to an embodiment.

FIG. 5 is a block diagram of a storage device according to an embodiment.

FIG. 6 is a termination resistor within a plurality of memory dies connected to a first channel according to an embodiment.

FIGS. 7 and 8 are broadcasting timing diagrams according to an embodiment.

FIGS. 9, 10 and 11 are two-chip interleaved timing diagrams according to an embodiment.

FIGS. 12, 13, 14, 15 and 16 are 4-chip interleaved timing diagrams according to an embodiment.

FIG. 17 is a block diagram of a storage device including a buffer chip according to an embodiment.

FIGS. 18 and 19 are block diagrams of a storage controller and buffer chip connected to a first channel according to an embodiment.

FIGS. 20 and 21 are timing diagrams for buffer chip broadcasting according to an embodiment.

FIGS. 22 and 23 are block diagrams of a buffer chip and a nonvolatile memory device connected to a second channel according to an embodiment.

FIGS. 24 and 25 are broadcast timing diagrams of a memory die according to an embodiment.

FIG. 26 is a diagram for explaining a memory system according to an embodiment of the present disclosure.

FIG. 27 is a block diagram exemplarily showing a mobile system to which a memory system according to an embodiment of the present disclosure is applied.

FIG. 28 is an example block diagram illustrating a computer device according to an embodiment.

### DETAILED DESCRIPTION OF THE EMBODIMENTS

Below, with reference to the attached drawings, embodiments of the present disclosure are described in detail so that a person having ordinary skill in the art to which the present disclosure pertains may easily practice the present disclosure. However, the present disclosure may be implemented in various different forms and is not limited to the embodiments described herein.

In order to clearly explain the present disclosure in the drawings, parts unrelated to the explanation are omitted, and similar parts are given similar drawing reference numerals throughout the specification. In the flowchart described with reference to the drawings, the order of operations may be changed, several operations may be merged, some operations may be split, and certain operations may not be performed.

Additionally, expressions written in the singular may be interpreted as singular or plural, unless explicit expressions such as "one" or "singular" are used. Terms that include ordinal numbers, such as first, second, etc., may be used to describe various components, but the components are not limited by these terms. These terms may be used to distinguish one component from another.

Hereinafter, the present disclosure will be described in more detail through examples. These examples are intended only to illustrate the present disclosure, and the scope of protection of the rights of the present disclosure is not limited by these examples.

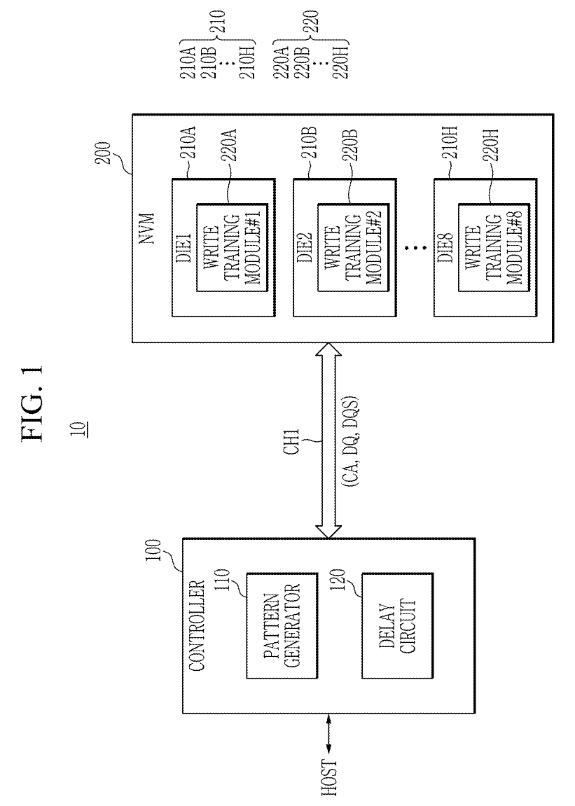

FIG. 1 is a block diagram of a storage device according to an embodiment.

Referring to FIG. 1, a storage device 10 may include a nonvolatile memory device 200 and a storage controller 100. The nonvolatile memory device 200 and the storage controller 100 may communicate through a first channel CH1. A command/address signal CA, a data signal DQ, and a data strobe signal DQS may be transmitted through the first channel CH1.

The storage controller 100 may control the nonvolatile memory device 200 to read data stored in the nonvolatile memory device 200 or to program data into the nonvolatile memory device 200 in response to a read/program request received from the host HOST. The storage controller 100 may control program, read, and erase operations for the nonvolatile memory device 200 by providing commands and addresses to the nonvolatile memory device 200. Additionally, data to program and read data may be transmitted and received between the storage controller 100 and the nonvolatile memory device 200.

The storage controller 100 may include a pattern generator 110 and a delay circuit 120. The pattern generator 110 may generate pattern data having a training pattern for writing training. The delay circuit 120 may output a data strobe signal and pattern data synchronized to the data strobe signal as training data according to a specific delay value.

A nonvolatile memory device 200 may include a first memory die 210A to an eighth memory die 210H. The nonvolatile memory device 200 may be an Octa Die Package ODP, but is not limited thereto. The nonvolatile memory device 200 may be a Dual Die Package DDP or a Quadruple Die Package QDP.

Each of the plurality of memory dies 210A to 210H included in the nonvolatile memory device 200 may include a write training module 220A to 220H that performs write training. The first memory die 210A may include a first write training module 220A, and the second memory die 210B may include a second write training module 220B. The eighth memory die 210H may include an eighth write training module 220H. In certain situations, such as booting or initialization, the write training modules 220A to 220H may perform write training to determine whether training data received from the storage controller 100 is pass/fail. The write training modules 220A to 220H may generate a pass/fail value by determining whether training data is pass/fail. Each of the plurality of memory dies 210A to 210H may transmit the generated pass/fail value to the storage controller 100.

The write training operation for a plurality of memory dies 210A to 210H included in the nonvolatile memory device 200 may be performed in a broadcasting manner. The write training operation for a plurality of memory dies 210A to 210H included in the nonvolatile memory device 200 may be performed in an interleaving manner. Even if the number of the plurality of memory dies 210A to 210H increases, the write training operation time may not increase significantly.

Specifically, each of the write training modules 220A to 220H may generate a pass/fail value indicating whether the training data passes or fails by comparing the training data and the pattern data. Each of the write training modules 220A to 220H may directly determine whether training data passes or fails, and transmit the pass/fail value to the storage controller 100 as small-sized data, for example, 1-byte data.

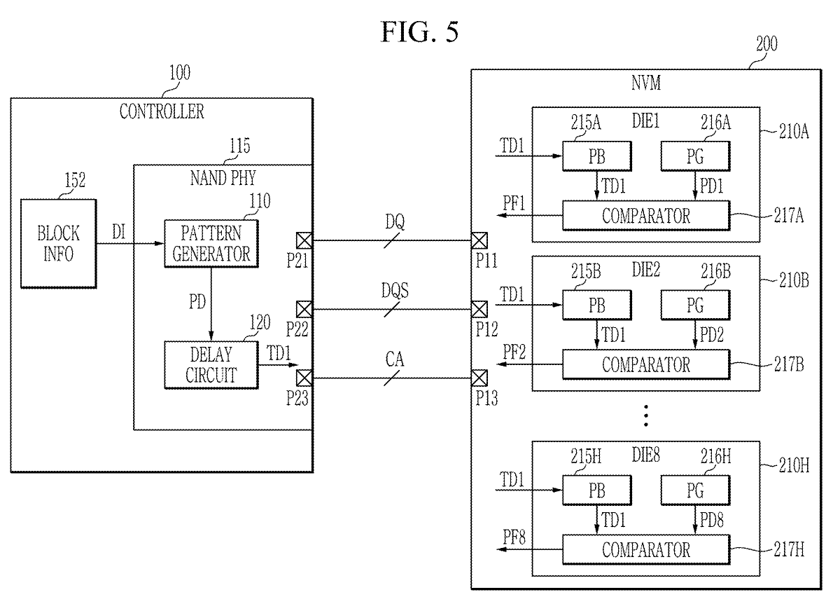

In an embodiment, the nonvolatile memory device 200 and the storage controller 100 may communicate in a Separate Command Address SCA manner in which commands and addresses are transmitted separately from data. Commands and addresses may be transmitted via command/address signal lines (e.g., CA in FIG. 5) synchronized to the command/address clock signal. Data may be transmitted over the data signal DQ line, synchronized to the data strobe signal DQS.

The nonvolatile memory device 200 and the storage controller 100 may be connected to each other through a plurality of pins, and training may be performed on data transmitted and received through the plurality of pins during an initialization or training operation.

In some embodiments, the storage device 10 may be an internal memory built into the electronic device. For example, the storage device 10 may be a solid state drive SSD, an embedded universal flash storage UFS memory device, or an embedded multi-media card (eMMC). In some embodiments, the storage device 10 may be an external memory removable to the electronic device. For example, the storage device 10 may be a UFS memory card, CF Compact Flash, SD Secure Digital, Micro-SD (Micro Secure Digital), Mini-SD (Mini Secure Digital), xD (extreme Digital), or Memory Stick.

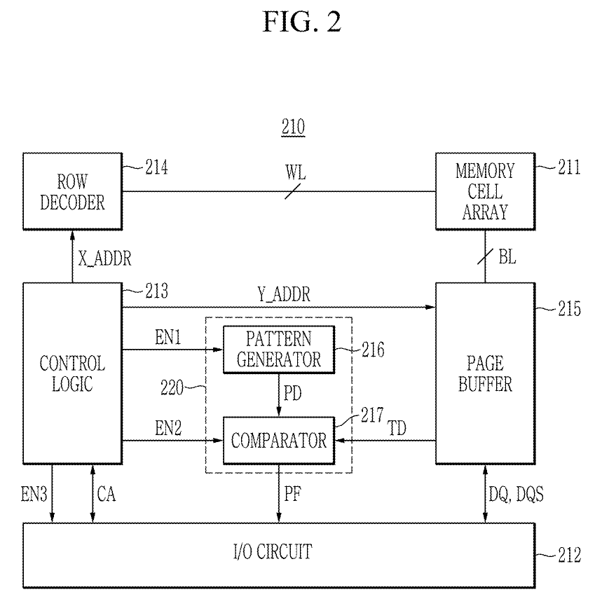

FIG. 2 is a block diagram of a memory die according to an embodiment.

Referring to FIGS. 1 and 2 together, a memory die 210 may include a memory cell array 211, a page buffer 215, a pattern generator 216, a comparator 217, control logic 213, a row decoder 214, and an input/output circuit 212. The memory die 210 may correspond to the first memory die 210A of FIG. 1, the second memory die 210B of FIG. 1, or the eighth memory die 210H of FIG. 1. A pattern generator 216 and a comparator 217 may constitute a writing training module 220 in FIG. 1.

The memory cell array 211 may include a plurality of nonvolatile memory cells, wherein the plurality of nonvolatile memory cells may be NAND flash memory cells. The plurality of non-volatile memory cells may be resistive memory cells such as ReRAM (resistive RAM), PRAM (phase change RAM), or MRAM (magnetic RAM). The memory cell array 211 may include volatile memory cells such as DRAM (Dynamic Random Access Memory) cells or SRAM (Static Random Access Memory) cells.

The memory cell array 211 may include a three-dimensional memory cell array. The three-dimensional memory cell array may include the plurality of cell strings or the plurality of NAND strings. A cell string may include memory cells each connected to word lines WLs stacked vertically on a substrate.

The input/output circuit 212 may receive a command/address signal CA, a data signal DQ, and a data strobe signal DQS from the storage controller 100. The input/output circuit 212 may transmit a command/address signal CA, a data signal DQ, and a data strobe signal DQS to the storage controller 100. For example, data DATA may be transmitted via a data signal DQ, and commands and addresses may be transmitted via a command/address signal CA.

The control logic 213 may receive commands and addresses from the storage controller 100. The control logic 213 may provide a row address X_ADDR to the row decoder 214. The control logic 213 may provide a column address Y_ADDR to the page buffer 215. The control logic 213 may output various control signals for programming data into the memory cell array 211 or reading data from the memory cell array 211. The control logic 213 may control various operations within the memory die 210.

The row decoder 214 may select one of a plurality of word lines WL in response to a row address X_ADDR. For example, during program operation, the row decoder 214 may apply a program voltage to a selection word line WL in a program execution section and apply a program verification voltage to a selection word line WL in a program verification section.

The page buffer 215 may select at least one bit line among a plurality of bit lines BL in response to a column address Y_ADDR. The page buffer 215 may operate as a write driver or a sense amplifier depending on the operating mode.

The page buffer 215 may be used as a buffer for storing training data TD during write training. During write training, training data TD may be stored in the page buffer 215 and then output without having to be stored in the memory cell array 211. By using the page buffer 215 for write training, the storage controller 100 may perform write training using a long length training pattern in the order of several kilobytes.

The pattern generator 216 may generate pattern data PD to be used for writing training and provide the generated pattern data PD to the comparator 217. The pattern generator 216 may include a linear feedback shift register LFSR.

The comparator 217 may receive training data TD from the page buffer 215 during write training. The comparator 217 may receive pattern data PD from the pattern generator 216. A comparator 217 may determine whether training data TD passes or fails by comparing training data TD and pattern data PD.

The input/output circuit 212 may receive a first command and an address that instructs a program operation through a command/address signal CA from the storage controller 100 during write training. The input/output circuit 212 may transmit the first command and address to the control logic 213. At this time, the first command may be a data input command or a program command.

The input/output circuit 212 may receive training data TD from the storage controller 100 through a data signal DQ during write training. The input/output circuit 212 may transmit training data TD to the page buffer 215.

The input/output circuit 212 may receive a second command instructing a comparison operation through a command/address signal CA from the storage controller 100. The input/output circuit 212 may transmit the second command to the control logic 213.

The control logic 213 may generate first and second enable signals EN1, EN2 in response to the second command. The control logic 213 may transmit the first and second enable signals EN1, EN2 to the pattern generator 216 and the comparator 217, respectively. The first and second enable signals EN1, EN2 may be the same signal.

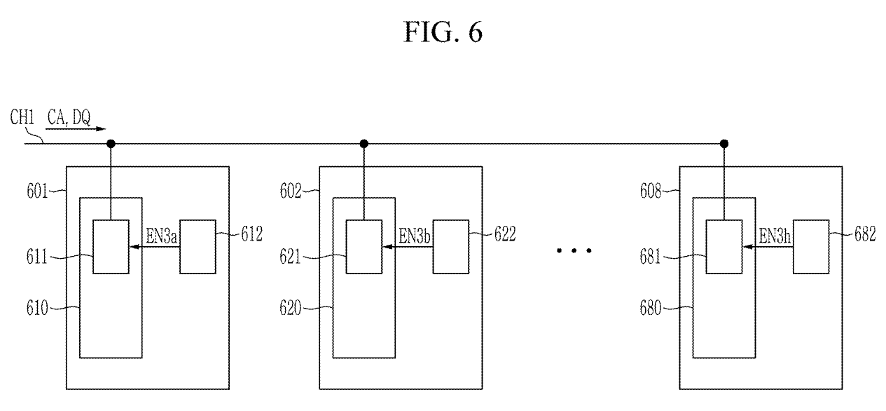

The control logic 213 may transmit a third enable signal to a termination resistor included in the memory die 210. The termination resistor may be turned on or off based on the third enable signal. This will be explained in detail in FIG. 6.

The pattern generator 216 may generate pattern data PD in response to the first enable signal EN1. A pattern generator 216 may provide pattern data PD to a comparator 217.

The comparator 217 may compare pattern data PD and training data TD in response to the second enable signal EN2. A comparator 217 may generate a pass/fail value PF based on the comparison result of pattern data PD and training data TD. If the training data TD corresponds to the pattern data PD, the comparator 217 may determine that the training data TD has passed. At this time, the comparator 217 may generate a pass/fail value PF as a first logic level. If the training data TD does not correspond to the pattern data PD, the comparator 217 may determine that the training data TD has failed. At this time, the comparator 217 may generate a pass/fail value PF as a second logic level.

The input/output circuit 212 may receive a third command requesting a pass/fail value from the storage controller 100 via a command/address signal CA. The input/output circuit 212 may transmit the third command to the control logic 213. The third command may be a status read command. The control logic 213 may control the comparator 217 and the input/output circuit 212 to output a pass/fail value PF in response to the third command. The comparator 217 may transmit a pass/fail value to the control logic 213 in response to the third command. The control logic 213 may transmit a status output command corresponding to the pass/fail value to the storage controller 100 through the input/output circuit 212.

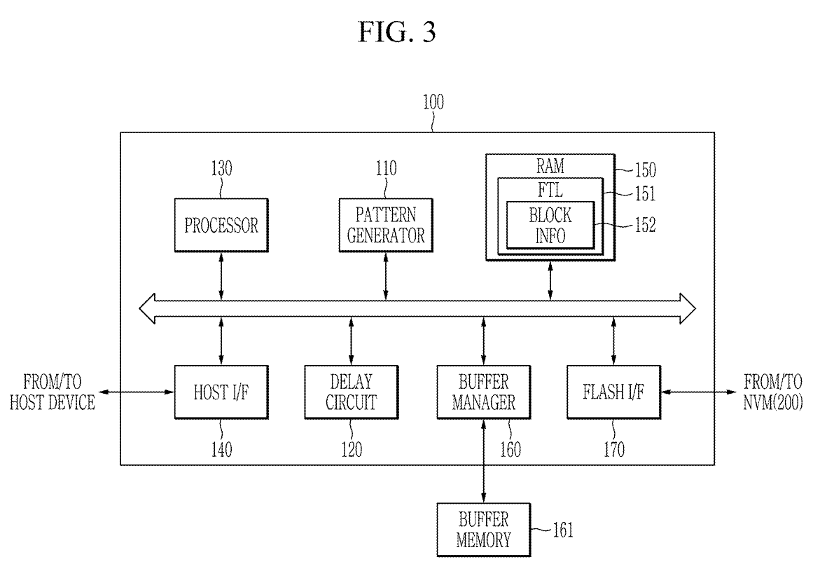

FIG. 3 is a block diagram of a storage controller according to an embodiment.

Referring to FIG. 3, the storage controller 100 may include a pattern generator 110, a delay circuit 120, at least one processor 130, a host interface circuit 140, a RAM 150, a buffer manager 160, and a flash interface circuit 170.

The pattern generator 110 may generate pattern data having a training pattern for writing training. The delay circuit 120 may output a data strobe signal and pattern data synchronized to the data strobe signal as training data according to a specific delay value.

The host interface circuit 140 may provide a physical connection between the host device and the storage device 10. The host interface circuit 140 may provide interfacing with the storage device 10 corresponding to the bus format of the host device. At least one of various interface methods such as USB, MMC, PCI-E, ATA, SATA, PATA, SCSI, SAS, ESDI, IDE, NVMe, etc. may be applied to the host interface circuit 140.

RAM 150 may be used as operating memory, cache memory, or buffer memory of the processor 130. RAM 150 may store codes and instructions executed by the processor 130. RAM 150 may store data processed by the processor 130. RAM 150 may be implemented as DRAM Dynamic RAM or SRAM Static RAM. RAM 150 may store firmware and data for controlling the storage controller 100. The stored firmware and data may be driven or processed by the processor 130. The software layer structure of the storage controller 100 implemented as firmware may include a flash translation layer 151.

The flash translation layer 151 may manage read and write operations of the nonvolatile memory device 200. The flash translation layer 151 may perform address mapping for interfacing between a nonvolatile memory device 200 and a host device. The flash translation layer 151 may include block information 152.

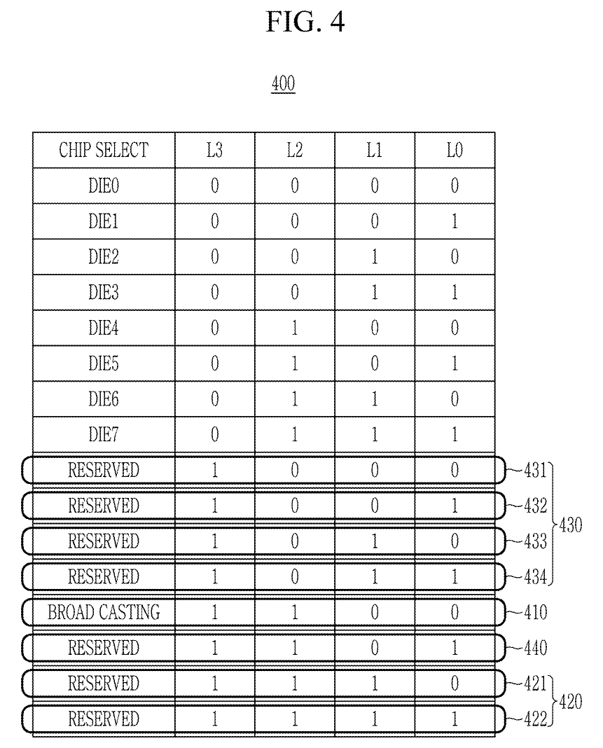

FIG. 4 is block information according to an embodiment.

The block information 152 may be matched with a logic unit number for selecting each of a plurality of memory dies. For example, logic unit number 00002 may be a number for selecting the first memory die 210A. Logic unit number 00012 may be a number for selecting the second memory die 210B. Logic unit number 01112 may be a number for selecting the 8th memory die 210H.

The block information 152 may be matched with a first logic unit number 410 for selecting all of the plurality of memory dies. For example, logic unit number 00002 may be the first logic unit number 410 for selecting the first memory die 210A. The write training operation for the plurality of memory dies 210A to 210H may be performed in a broadcasting manner.

The block information 152 may be matched with a second logic unit number 420 for selecting the first group die and the second group die. The first group die may include a first memory die to a fourth memory die 210A to 210D. The second group die may include the fifth to eighth memory dies 210E to 210H. For example, logic unit number 11102 may be the 2-1 logic unit number 421 for selecting the first group die. Logic unit number 11112 may be the 2-2 logic unit number 422 for selecting the 2nd group die. The write training operation for the plurality of memory dies 210A to 210H may be performed in a 2-chip interleaved manner.

The block information 152 may be matched with a third logic unit number 430 for selecting the first group die, the second group die, the third group die, and the fourth group die. The first group die may include a first memory die 210A and a second memory die 210B. The second group die may include a third memory die 210C and a fourth memory die 210D. The third group die may include a fifth memory die 210E and a sixth memory die 210F. The fourth group die may include a seventh memory die 210G and an eighth memory die 210H. For example, logic unit number 10002 may be the 3-1 logic unit number 431 for selecting the first group die. Logic unit number 10012 may be the 3-2 logic unit number 432 for selecting the second group die. Logic unit number 10102 may be the 3-3 logic unit number 433 for selecting the 3rd group die. Logic unit number 10112 may be the 3-4 logic unit number 434 for selecting the 4th group die. The write training operation for the plurality of memory dies 210A to 210H may be performed in a 4-chip interleaved manner.

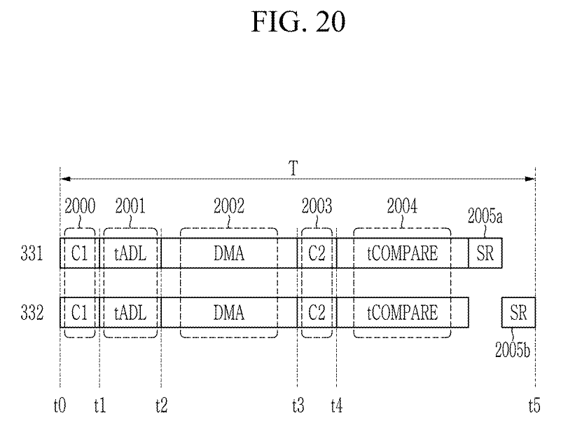

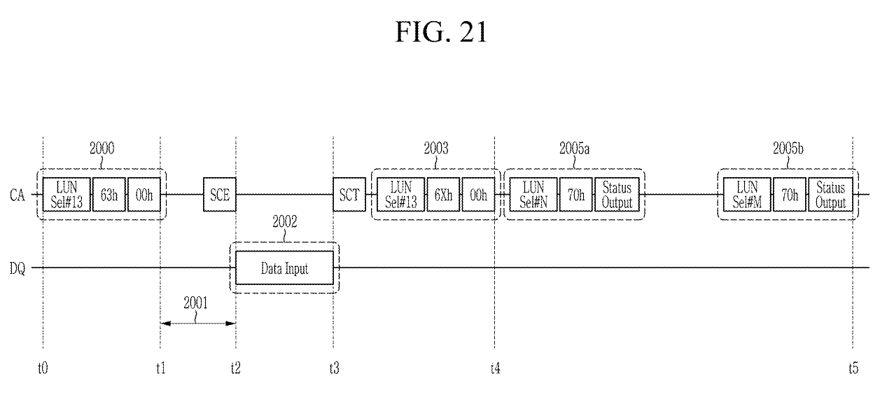

The block information 152 may be matched with a fourth logic unit number 440 for selecting the first write training module and the second write training module included in the buffer chip. The writing training operations for the first writing training module and the second writing training module may be performed in a broadcast manner. This will be explained in detail in FIGS. 20 and 21.

Referring again to FIG. 3, the processor 130 may control the operation of the storage controller 100 in response to a command received from the host device through the host interface circuit 140. The processor 130 may communicate with a nonvolatile memory device 200 via a flash interface circuit 170. The processor 130 may communicate with the buffer memory 161 through the buffer manager 160.

The processor 130 may perform the write training operation in a broadcast manner if sufficient power is supplied to the storage controller 100 and the system power budget is within an acceptable range. The processor 130 may generate a command based on a first logic unit number 410 that selects all of the plurality of memory dies.

The processor 130 may perform the write training operation in a two-chip interleaved manner if the system power budget is below the first threshold. The processor 130 may generate a command based on a second logic unit number 420 that selects a first group die and a second group die.

The processor 130 may perform the write training operation in a 4-chip interleaved manner when the system power budget is greater than or equal to a first threshold and less than or equal to a second threshold. The processor 130 may generate a command based on a third logic unit number 430 that selects a first group die, a second group die, a third group die, and a fourth group die.

The buffer manager 160 is configured to control the buffer memory 161 under the control of the processor 130. The buffer manager 160 controls the buffer memory 161 to temporarily store data exchanged between the nonvolatile memory device 200 and the host device.

Buffer memory 161 may store commands and data executed and processed by the storage controller 100. The buffer memory 161 may temporarily store data that is stored in the nonvolatile memory device 200 or data that is to be stored.

Buffer memory 161 may be implemented as volatile memory such as DRAM (Dynamic Random Access Memory), SRAM Static RAM, etc. However, it is not limited thereto, and the buffer memory 161 may be implemented with various types of nonvolatile memory, such as a resistive nonvolatile memory such as MRAM (magnetic RAM), PRAM (phase change RAM), or ReRAM (resistive RAM), flash memory, NFGM (Nano Floating Gate Memory), PoRAM (Polymer Random Access Memory), or FRAM (Ferroelectric Random Access Memory). In this embodiment, the buffer memory 161 is illustrated as being provided outside the storage controller 100, but is not limited thereto, and the buffer memory 161 may be provided inside the storage controller 100.

The flash interface circuit 170 may communicate with a nonvolatile memory device 200. The flash interface circuit 170 may transmit data to the plurality of memory dies 210 in FIG. 1. The flash interface circuit 170 may receive data read from the plurality of memory dies 210. The flash interface circuit 170 may transmit a command signal to a memory die 210 included in a nonvolatile memory device 200 corresponding to a logic unit number. At this time, the command signal may mean a memory die 210 selection command.

FIG. 5 is a block diagram of a storage device according to an embodiment.

Referring to FIG. 5, the storage device 10 of FIG. 1 may include a nonvolatile memory device 200 and a storage controller 100. A nonvolatile memory device 200 and a storage controller 100 may communicate in the SCA manner in which commands and addresses are transmitted separately from data. The nonvolatile memory device 200 may include first to eighth memory dies 210A to 210H. A nonvolatile memory device 200 may include a plurality of pins P11 to P13.

A nonvolatile memory device 200 may transmit and receive a data signal DQ to and from a storage controller 100 through a data pin P11. A nonvolatile memory device 200 may transmit and receive a data strobe signal DQS to and from a storage controller 100 via a data strobe pin P12. The nonvolatile memory device 200 may receive a command/address signal CA from the storage controller 100 through the command/address pin P13.

The storage controller 100 may include a plurality of pins P21 to P23 each connected to a plurality of pins P11 to P13 of a nonvolatile memory device 200. At this time, signal lines through which a data signal DQ, a data strobe signal DQS, and a command/address signal CA are transmitted may constitute a first channel CH1 in FIG. 1.

The storage controller 100 may include a RAM 150 in FIG. 3, a pattern generator 110, and a delay circuit 120. RAM 150 may store block information 152 including a plurality of logic unit numbers DI corresponding to a plurality of memory dies 210A to 210H. The pattern generator 110 and delay circuit 120 may be included in the nonvolatile memory interface 115. The nonvolatile memory device 200 may include NAND flash memory. The nonvolatile memory interface 115 may correspond to a NAND physical layer, i.e., a NAND PHY.

The pattern generator 110 may obtain a logic unit number DI corresponding to a memory die from block information 152. A pattern generator 110 may generate pattern data PD having a training pattern based on a logic unit number DI. The delay circuit 120 may output a data strobe signal DQS and pattern data PD synchronized to the data strobe signal DQS as first training data TD1 according to a specific delay value.

The first memory die 210A may include a page buffer 215A, a pattern generator 216A, and a comparator 217A. The page buffer 215A may receive first training data TD1 from the storage controller 100. The page buffer 215A may store first training data TD1.

The pattern generator 216A may generate first pattern data PD1. The first pattern data PD1 may be identical to the pattern data PD generated by the pattern generator 110. A comparator 217A may generate a first pass/fail value PF1 indicating whether the first training data TD1 passes or fails by comparing the first training data TD1 with the first pattern data PD1.

The second memory die 210B may include a page buffer 215B, a pattern generator 216B, and a comparator 217B. The page buffer 215B may receive first training data TD1 from the storage controller 100. The page buffer 215B may store first training data TD1.

The pattern generator 216B may generate second pattern data PD2. The second pattern data PD2 may be identical to the pattern data PD generated by the pattern generator 110. A comparator 217B may generate a second pass/fail value PF2 indicating whether the first training data TD1 passes or fails by comparing the first training data TD1 with the second pattern data PD2.

The eighth memory die 100H may include a page buffer 215H, a pattern generator 216H, and a comparator 217H. The operations of the page buffer 215H, the pattern generator 216H, and the comparator 217H may be substantially similar to the operations of the page buffer 215B, the pattern generator 216H, and the comparator 217B.

The pattern generator 216A to 216H may be synchronized with the pattern generator 110 of the storage controller 100. For example, the same initial value, i.e., seed, may be input to the pattern generators 110, 216A to 216H, and a polynomial representing the arrangement of taps used to generate the next state may be applied to the pattern generators 110, 216A to 216H. Accordingly, the pattern data PD generated by the pattern generator 110 of the storage controller 100 may be identical to the first to eighth pattern data PD1 to PD8 generated by each of the pattern generators 216A to 216H.

FIG. 6 is a termination resistor within a plurality of memory dies connected to a first channel according to an embodiment.

Referring to FIG. 6, a plurality of memory dies 601 to 608 may be electrically connected to each other through a first channel CH1. The plurality of memory dies 601 to 608 may each correspond to the plurality of memory dies 210A to 210H of FIG. 1.

A plurality of memory dies 601 to 608 may include a plurality of input/output circuits 610 to 680 and a plurality of control logic 612 to 682. For example, a first memory die 601 may include a first input/output circuit 610 and a first control logic 612. The second memory die 602 may include a second input/output circuit 620 and a first control logic 622. The third to eighth memory dies 603 to 608 may also include input/output circuits and control logic, similar to the first memory die 601 and the second memory die 602, respectively.

The plurality of input/output circuits 610 to 680 may include a plurality of termination resistors 611 to 681. For example, the first input/output circuit 610 may include a first termination resistor 611. The second input/output circuit 620 may include a second termination resistor 621. The third input/output circuit and the fourth input/output circuit 630 to 680 may each include a termination resistor, similar to the first input/output circuit 610 and the second input/output circuit 620.

A command/address signal CA and a data signal DQ may be transmitted to the plurality of memory dies 601 to 608 through the first channel CH1. Multiple termination resistors 611 to 681 may maintain signal integrity SI by matching the impedance of the command/address signal line and the data signal line to reduce reflections.

The resistance values of the plurality of terminal resistors 611 to 681 may be different from each other. For example, the resistance value of the first terminal resistor 611 may be 200 Ω, and the resistance values of the second to eighth terminal resistors 621 to 681 may be 300 Ω. The resistance values of the plurality of terminal resistors 611 to 681 may be changed based on the environment of the channel.

The environment of a channel may refer to the characteristics of the signal lines through which the command/address signals CA and data signals DQ travel. The characteristic impedance of a signal line may be determined by the width, thickness, and spacing of the signal line. The impedance of the signal line may be different between the plurality of memory dies 601 to 608 sharing one channel CH1. If the impedance of the signal line is high, the resistance value of the terminating resistor may be set high. If the impedance of the signal line is low, the resistance value of the terminating resistor may be set low. For example, the resistance value of the first terminal resistor 611 may be 200 Ω, and the resistance values of the second to eighth terminal resistors 621 to 681 may be 300 Ω. The resistance values of the plurality of terminal resistors 611 to 681 may be changed based on the environment of the channel. However, for convenience of explanation, it will be assumed that all of the memory dies 601 to 608 have the same resistance value.

Among the plurality of memory dies 601 to 608, the eighth memory die 608 located at the end may have a worse channel environment than the plurality of memory dies 601 to 607 excluding the eighth memory die 608 due to reasons such as an increased length of the transmission line. Accordingly, the eighth termination resistor 681 of the eighth memory die 608 may be set to have a higher resistance value than the termination resistors 611 to 671 of the plurality of memory dies 601 to 607. However, the present disclosure is not limited thereto, and the terminal resistance value of a memory die having a worse channel environment than the 8th memory die 608 may be set higher.

A plurality of control logics 612 to 682 may transmit a plurality of third enable signals EN3a to EN3h that determine on or off of a plurality of termination resistors 611 to 681 to the plurality of termination resistors 611 to 681. The plurality of terminal resistors 611 to 681 may be turned on or off based on the plurality of third enable signals EN3a to EN3h, respectively. When the plurality of termination resistors 611 to 681 are turned on, they may be electrically connected to the first channel CH1. When the plurality of termination resistors 611 to 681 are turned off, they cannot be electrically connected to the first channel CH1.

For example, the eighth control logic 682 may transmit the 3-8th enable signal EN3h that determines the on state of the eighth termination resistor 681 to the eighth termination resistor 681. The eighth terminal resistor 681 may be electrically connected to the first channel CH1. The first control logic to the seventh control logic 612 to 672 may transmit the third-first enable signal to the third-seventh enable signal EN3a to EN3g that determines the turn-off of the first to seventh termination resistors 611 to 671, respectively, to the first to seventh termination resistors 611 to 671. The first to seventh terminal resistors 611 to 671 cannot be electrically connected to the first channel CH1.

The states of the plurality of third enable signals EN3a to EN3h may be fixed while the plurality of memory dies 601 to 608 perform write training through the first channel CH1. Write training may include program operations in which a plurality of memory dies 601 to 608 receive training data from a storage controller 100 of FIG. 1 via a first channel CH1. Write training may include a state read operation in which pass/fail values generated from the plurality of memory dies 601 to 608 are transmitted to the storage controller 100 via a first channel CH1. While performing the write training, the 8th terminal resistor 681 may be maintained in a state of being electrically connected to the first channel CH1 based on the 3-8th enable signal EN3h. The first to seventh terminal resistors 611 to 671 may be maintained in a state where they are not electrically connected to the first channel CH1 based on the third-first to third-seventh enable signals EN3a to EN3g.

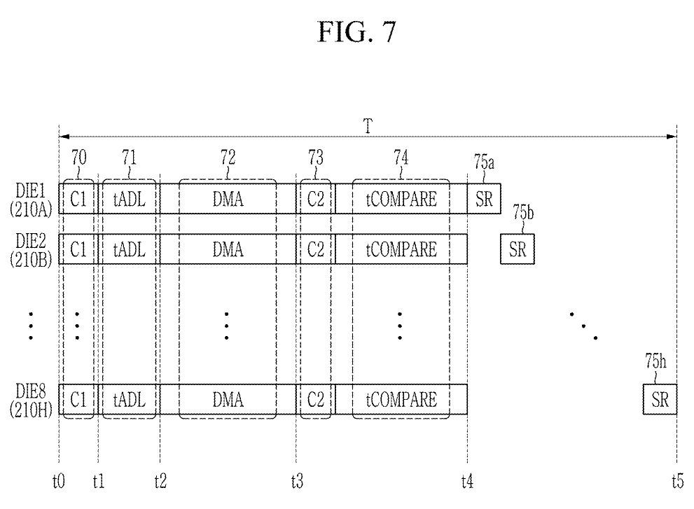

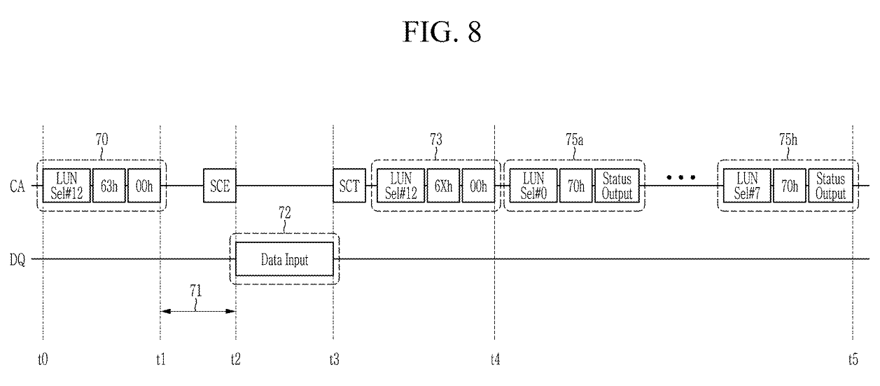

FIGS. 7 and 8 are broadcasting timing diagrams according to an embodiment.

The write training operation may include a first transfer operation via a command/address signal CA line and a command/address pin P13, and a second transfer operation via a data signal DQ line and a data pin P11. By performing the first transfer operation for the first to eighth memory dies 210A to 210H in a broadcast manner, the idle time for the command/address signal CA lines may be reduced. By performing the second transfer operation for the first to eighth memory dies 210A to 210H in a broadcast manner, the idle time for the data signal DQ lines may be reduced.

Below, the specific operations for the first to eighth memory dies 210A to 210H will be described.

Referring to FIGS. 7 and 8, at t0 to t1, a plurality of memory dies 210A to 210H may perform a first command receiving operation 70 to receive a first command C1 instructing a program operation. A storage controller 100 of FIG. 1 may sequentially transmit a logic unit number selection signal LUNSEL#12 for selecting a first logic unit number 410 of FIG. 4, a program instruction command 63h, and a standby command 00h to a plurality of memory dies 210A to 210H (i.e., a first command receiving operation (70) of the plurality of memory dies 210A to 210H).

At t1 to t2, the plurality of memory dies 210A to 210H may be ready to receive first training data TD1 after a data loading time (tADL) 71.

At t2 to t3, a DMA write operation 72 may be performed to transfer first training data TD1 to the plurality of memory dies 210A to 210H from the storage controller 100. The storage controller 100 may transmit first training data TD1 to a plurality of memory dies 210A to 210H (i.e., DMA write operation (72) of the plurality of memory dies 210A to 210H). At this time, the storage controller 100 may transmit a command SCE instructing the start of data transfer to the plurality of memory dies 210A to 210H immediately before the DMA write operation 72. The storage controller 100 may transmit a command SCT indicating termination of data transfer to the plurality of memory dies 210A to 210H after a DMA write operation 72.

At t3 to t4, the plurality of memory dies 210A to 210H may perform a second command receiving operation 73 that receives a second command C2 instructing a comparison operation. The storage controller 100 may sequentially transmit a logic unit number selection signal LUNSEL#12 for selecting a first logic unit number 410, a compare operation instruction command 6Xh, and a standby command 00h to a plurality of memory dies 210A to 210H (a second command receiving operation (73) of the plurality of memory dies 210A to 210H). A plurality of memory dies 210A to 210H may perform a comparison operation (tCOMPARE) 74 of the first training data TD1 and the pattern data PD1 to PD8 based on a comparison operation instruction command 6Xh.

At t4 to t5, the first to eighth memory dies 210A to 210H may sequentially receive a status read command and perform a status read operation SR that transmits a pass/fail value PF in response to the status read command.

The first memory die 210A may receive a status read command and perform a status read operation SR 75a that transmits a first pass/fail value PF1 in response to the status read command. The storage controller 100 may transmit a logic unit number selection signal LUNSEL#0 and a status read instruction command 70h to the first memory die 210A to select a logic unit number corresponding to the first memory die 210A as a status read operation SR 75a. The first memory die 210A may transmit a status output command Status Output to the storage controller 100 in response to the status read instruction command 70h (i.e., the status read operation (SR) 75a of the first memory die 210A).

The eighth memory die 210H may receive a status read command and perform a status read operation SR 75h that transmits an eighth pass/fail value PF8 in response to the status read command. The storage controller 100 may transmit a logic unit number selection signal LUNSEL#7 for selecting a logic unit number corresponding to the first memory die 210H and a status read instruction command 70h to the eighth memory die 210H as a status read operation SR 75h. The eighth memory die 210H may transmit a status output command Status Output to the storage controller 100 in response to the status read instruction command 70h (i.e., the status read operation (SR) 75h of the eighth memory die 210H).

The status read operations SR 75b to 75g of the second to seventh memory dies 210B to 210G are also identical to the descriptions of the status read operations SR 75a of the first memory die 210A and the eighth memory die 210H 75h.

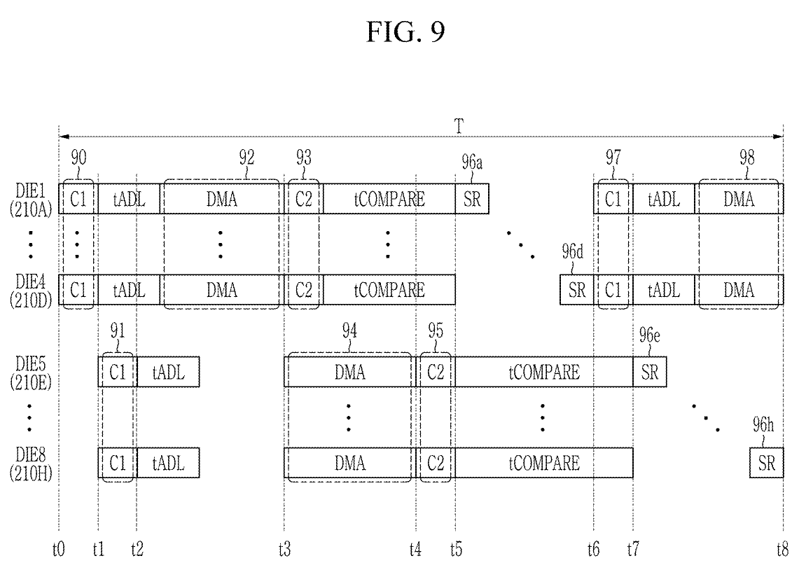

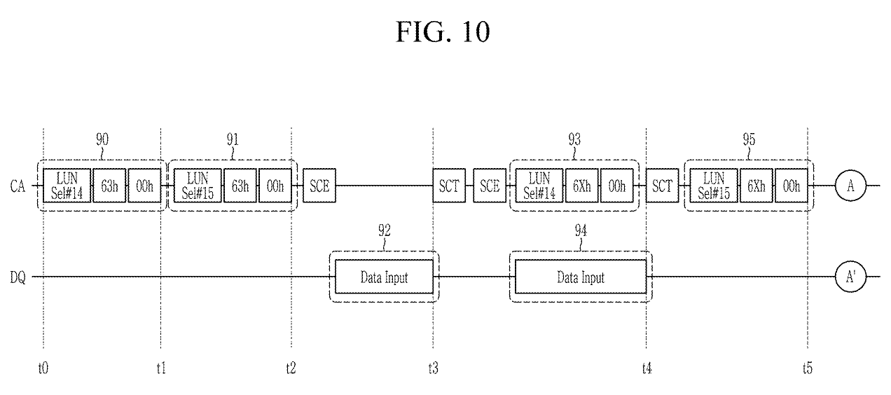

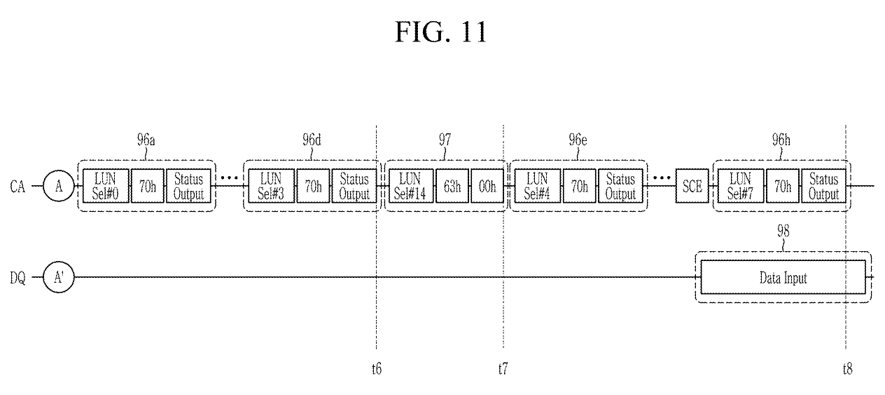

FIGS. 9 to 11 are two-chip interleaved timing diagrams according to an embodiment.

The write training operation may include a first transfer operation via a command/address signal CA line and a command/address pin P13, and a second transfer operation via a data signal DQ line and a data pin P11. By performing the first transfer operation for the first to eighth memory dies 210A to 210H in a two-chip interleaved manner, the idle time for the command/address signal CA lines may be reduced. By performing the second transfer operation for the first to eighth memory dies 210A to 210H in a two-chip interleaved manner, the idle time for the data signal DQ lines may be reduced.

Below, the specific operations for the first to eighth memory dies 210A to 210H will be described.

Referring to FIGS. 9 to 11, at t0 to t1, a plurality of memory dies 210A to 210D may perform a first command receiving operation 90 that receives a first command C1 instructing a program operation at substantially the same timing. The storage controller 100 in FIG. 1 may sequentially transmit a logic unit number selection signal LUNSEL#14 for selecting a 2-1 logic unit number 421 in FIG. 4, a program instruction command 63h, and a standby command 00h to a plurality of memory dies 210A to 210D. (i.e., the first command receiving operation (90) of the plurality of memory dies 210A to 210D).

At t1 to t2, the plurality of memory dies 210E to 210H may perform a first command receiving operation 91 that receives a first command C1 instructing a program operation. The storage controller 100 may sequentially transmit a logic unit number selection signal LUNSEL#15 for selecting a 2-2 logic unit number 422 in FIG. 4, a program instruction command 63h, and a standby command 00h to a plurality of memory dies 210E to 210H (i.e., a first command receiving operation (91) of the plurality of memory dies 210E to 210H.

At t2 to t3, a DMA write operation 92 may be performed to transfer first training data TD1 in FIG. 5 to the plurality of memory dies 210A to 210D from the storage controller 100 at substantially the same timing. The storage controller 100 may transmit first training data TD1 to a plurality of memory dies 210A to 210D (i.e., a DMA write operation (92) of the plurality of memory dies 210A to 210D). At this time, the storage controller 100 may transmit a command SCE instructing the start of data transfer to the plurality of memory dies 210A to 210D immediately before the DMA write operation 92. The storage controller 100 may transmit a command SCT indicating termination of data transfer to the plurality of memory dies 210A to 210D after a DMA write operation 92.

At t3 to t4, the plurality of memory dies 210A to 210D may perform a second command receiving operation 93 that receives a second command C2 instructing a comparison operation. The storage controller 100 may sequentially transmit a logic unit number selection signal LUNSEL#14 for selecting a 2-1 logic unit number 421, a compare operation instruction command 6Xh, and a standby command 00h to a plurality of memory dies 210A to 210D (second command receiving operation (93) of the plurality of memory dies 210A to 210D). A plurality of memory dies 210A to 210D may perform a comparison operation (tCOMPARE) between the first training data TD1 and the pattern data PD1 to PD4 based on a comparison operation instruction command 6Xh.

At t3 to t4, a DMA write operation 94 may be performed to transfer first training data TD1 to the plurality of memory dies 210E to 210H from the storage controller 100. The storage controller 100 may transmit first training data TD1 to a plurality of memory dies 210E to 210H (i.e., a DMA write operation (94) of the plurality of memory dies 210E to 210H). At this time, the storage controller 100 may transmit a command SCE instructing the start of data transfer to the plurality of memory dies 210E to 210H immediately before the DMA write operation 94. The storage controller 100 may transmit a command SCT indicating termination of data transfer to the plurality of memory dies 210E to 210H after a DMA write operation 94.

The comparison operation (tCOMPARE) of the first to fourth memory dies 210A to 210D may be performed in parallel with the DMA write operation 94 of the fifth to eighth memory dies 210E to 210H. While the comparison operation (tCOMPARE) of the first to fourth memory dies 210A to 210D is performed, the first training data TD1 may be transmitted to the fifth to eighth memory dies 210E to 210H through the data signal DQ line of the first channel CH1. The idle time of the data signal DQ line of the first channel CH1 may be reduced. By performing write training in a two-chip interleaved manner, the write training operation time may be reduced.

At t4 to t5, the plurality of memory dies 210E to 210H may perform a second command receiving operation 95 that receives a second command C2 instructing a comparison operation. The storage controller 100 may sequentially transmit a logic unit number selection signal LUNSEL#15 for selecting a 2-2 logic unit number 422, a compare operation instruction command 6Xh, and a standby command 00h to a plurality of memory dies 210E to 210H (second command receiving operation (95) of the plurality of memory dies 210E to 210H). A plurality of memory dies 210E to 210H may perform a comparison operation (tCOMPARE) between the first training data TD1 and the pattern data PD5 to PD8 based on a comparison operation instruction command 6Xh.

At t5 to t6, the first to fourth memory dies 210A to 210D may sequentially receive a status read command and perform a status read operation SR to transmit a pass/fail value PF in response to the status read command.

The first memory die 210A may receive a status read command and perform a status read operation SR 96a that transmits a first pass/fail value PF1 in response to the status read command. The storage controller 100 may transmit a logic unit number selection signal LUNSEL#0 and a status read instruction command 70h to the first memory die 210A to select a logic unit number corresponding to the first memory die 210A as a status read operation SR 96a. The first memory die 210A may transmit a status output command Status Output to the storage controller 100 in response to the status read instruction command 70h (i.e., the status read operation (SR) 96a of the first memory die 210A).

The fourth memory die 210D may receive a status read command and perform a status read operation SR 96d that transmits a fourth pass/fail value PF4 in response to the status read command. The storage controller 100 may transmit a logic unit number selection signal LUNSEL#3 and a status read instruction command 70h to the fourth memory die 210D to select a logic unit number corresponding to the fourth memory die 210D as a status read operation SR 96d. The fourth memory die 210D may transmit a status output command Status Output to the storage controller 100 in response to the status read instruction command 70h (i.e., the status read operation (SR) 96d of the fourth memory die 210D).

The state read operations SR 96b and 96c of the second memory die 210B and the third memory die 210C are also identical to the description of the state read operations SR 96a of the first memory die 210A and the fourth memory die 210D 96d.

The state read operation SR 96a to 96d of the first to fourth memory dies 210A to 210D may be performed in parallel with the compare operation (tCOMPARE) of the fifth to eighth memory dies 210E to 210H.

While the compare operation (tCOMPARE) of the fifth to eighth memory dies 210E to 210H is performed, a status read command may be transmitted to the first to fourth memory dies 210A to 210D through the command/address signal CA line of the first channel CH1. The idle time of the command/address signal CA line of the first channel CH1 may be reduced. By performing write training in a two-chip interleaved manner, the write training operation time may be reduced.

At t6 to t7, the plurality of memory dies 210A to 210D may perform a first command receiving operation 97 that receives a first command C1 instructing a program operation. The storage controller 100 may sequentially transmit a logic unit number selection signal LUNSEL#14 for selecting a 2-1 logic unit number 421 of FIG. 4, a program instruction command 63h, and a standby command 00h to a plurality of memory dies 210A to 210D (i.e., a first command receiving operation (97) of the plurality of memory dies 210A to 210D.

At t7 to t8, the fifth to eighth memory dies 210E to 210H may sequentially receive a status read command and perform a status read operation SR to transmit a pass/fail value PF in response to the status read command.

The fifth memory die 210E may receive a status read command and perform a status read operation SR 96e that transmits a fifth pass/fail value PF5 in response to the status read command. The storage controller 100 may transmit a logic unit number selection signal LUNSEL#4 and a status read instruction command 70h to the fifth memory die 210E to select a logic unit number corresponding to the fifth memory die 210E as a status read operation SR 96e. The fifth memory die 210E may transmit a status output command Status Output to the storage controller 100 in response to the status read instruction command 70h (i.e., the status read operation (SR) 96e of the fifth memory die 210E).

The eighth memory die 210H may receive a status read command and perform a status read operation SR 96h that transmits an eighth pass/fail value PF8 in response to the status read command. The storage controller 100 may transmit a logic unit number selection signal LUNSEL#7 for selecting a logic unit number corresponding to the first memory die 210H and a status read instruction command 70h to the eighth memory die 210H as a status read operation SR 96h. The eighth memory die 210H may transmit a status output command Status Output to the storage controller 100 in response to the status read instruction command 70h (i.e., the status read operation (SR) 96h of the eighth memory die 210H).

The state read operations SR 96f and 96g of the sixth memory die 210F and the seventh memory die 210G are also identical to the description of the state read operations SR 96e of the fifth memory die 210E and the eighth memory die 210H 96h.

A DMA write operation 98 may be performed in the storage controller 100 to transmit first training data TD1 to the plurality of memory dies 210A to 210D. The storage controller 100 may transmit first training data TD1 to a plurality of memory dies 210A to 210D (i.e., a DMA write operation (98) of the plurality of memory dies 210A to 210D). At this time, the storage controller 100 may transmit a command SCE instructing the start of data transfer to the plurality of memory dies 210A to 210D immediately before the DMA write operation 98.

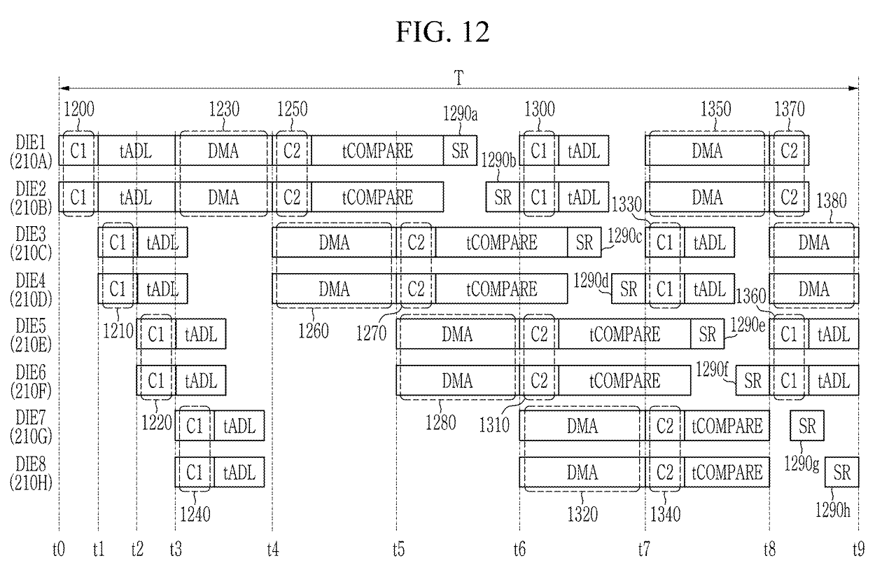

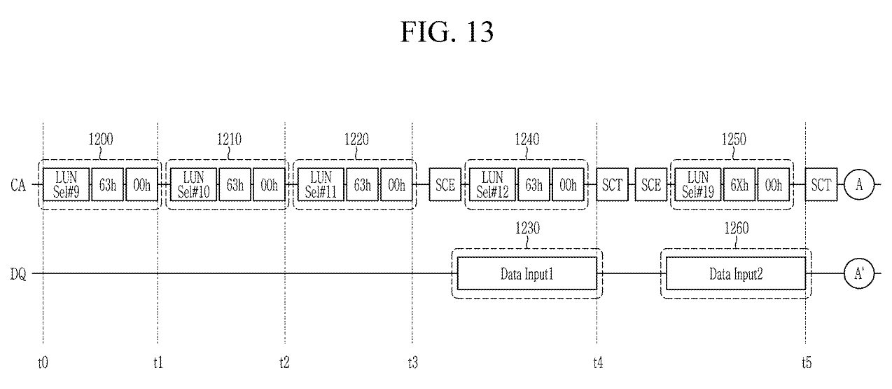

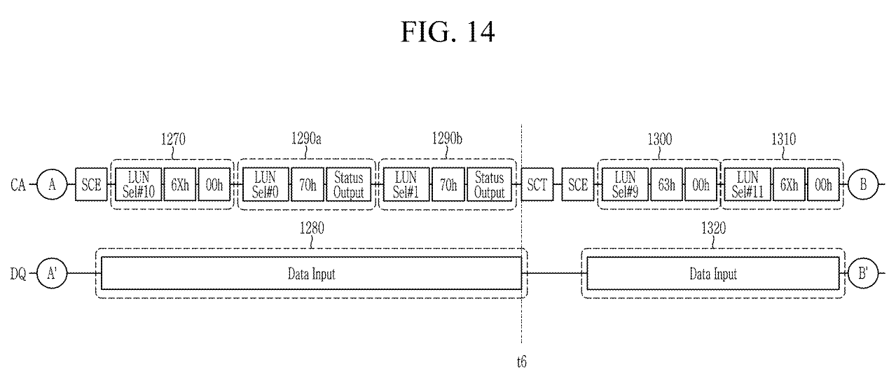

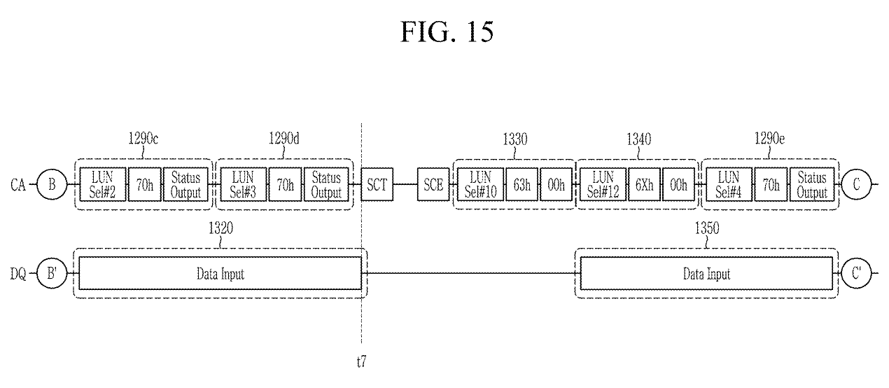

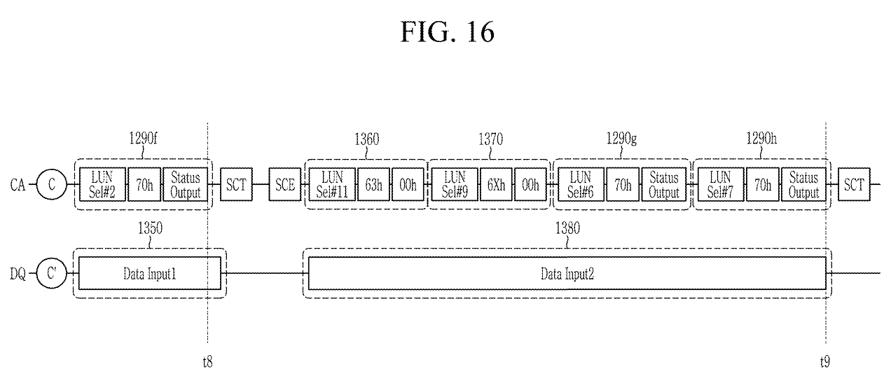

FIGS. 12 to 16 are 4-chip interleaved timing diagrams according to an embodiment.

The write training operation may include a first transfer operation via a command/address signal CA line and a command/address pin P13, and a second transfer operation via a data signal DQ line and a data pin P11. By performing the first transfer operation for the first to eighth memory dies 210A to 210H in a four-chip interleaved manner, the idle time for the command/address signal CA lines may be reduced. By performing the second transfer operation for the first to eighth memory dies 210A to 210H in a four-chip interleaved manner, the idle time for the data signal DQ lines may be reduced.

Below, the specific operations for the first to eighth memory dies 210A to 210H will be described.

Referring to FIGS. 12 to 16, at t0 to t1, the first memory die 210A and the second memory die 210B may perform a first command receiving operation 1200 that receives a first command C1 instructing a program operation at substantially the same timing. The storage controller 100 in FIG. 1 may sequentially transmit a logic unit number selection signal LUNSEL#9 for selecting the 3-1 logic unit number 431 in FIG. 4, a program instruction command 63h, and a standby command 00h to a plurality of memory dies 210A, 210B. (i.e., the first command receiving operation (1200) of the first memory die 210A and the second memory die 210B).

At t1 to t2, the third memory die 210C and the fourth memory die 210D may perform a first command receiving operation 1210 that receives a first command C1 instructing a program operation at substantially the same timing. The storage controller 100 may sequentially transmit a logic unit number selection signal LUNSEL#10 for selecting a 3-2 logic unit number 432 in FIG. 4, a program instruction command 63h, and a standby command 00h to a plurality of memory dies 210C, 210D (i.e., a first command receiving operation (1210) of the 3rd memory die 210C and the 2nd memory die 210D).

At t2 to t3, the fifth memory die 210E and the sixth memory die 210F may perform a first command receiving operation 1220 that receives a first command C1 instructing a program operation at substantially the same timing. The storage controller 100 may sequentially transmit a logic unit number selection signal LUNSEL#11 for selecting the 3-3 logic unit number 433 in FIG. 4, a program instruction command 63h, and a standby command 00h to a plurality of memory dies 210E, 210F (i.e., the first command receiving operation (1220) of the fifth memory die 210E and the sixth memory die 210F.

At t3~t4, the seventh memory die 210G and the eighth memory die 210H may perform a first command receiving operation 1240 that receives a first command C1 instructing a program operation at substantially the same timing. The storage controller 100 may sequentially transmit a logic unit number selection signal LUNSEL#12 for selecting a 3rd-4th logic unit number 434 in FIG. 4, a program instruction command 63h, and a standby command 00h to a plurality of memory dies 210G, 210H (i.e., a first command receiving operation (1240) of the 7th memory die 210G and the 8th memory die 210H).

A DMA write operation 1230 may be performed to transfer first training data TD1 in FIG. 5 to the first memory die 210A and the second memory die 210B at substantially the same timing in the storage controller 100. The storage controller 100 may transmit first training data TD1 to the first memory die 210A and the second memory die 210B (i.e., DMA write operation (1230) of the plurality of memory dies 210A and 210B). At this time, the storage controller 100 may transmit a command SCE instructing the start of data transfer to the first memory die 210A and the second memory die 210B immediately before the DMA write operation 1230. The storage controller 100 may transmit a command SCT indicating termination of data transfer to the first memory die 210A and the second memory die 210B after the DMA write operation 1230.

At t4~t5, the first memory die 210A and the second memory die 210B may perform a second command receiving operation 1250 that receives a second command C2 instructing a comparison operation at substantially the same timing. The storage controller 100 may sequentially transmit a logic unit number selection signal LUNSEL#9 for selecting a 3-1 logic unit number 431, a compare operation instruction command 6Xh, and a standby command 00h to the first memory die 210A and the second memory die 210B (second command receiving operation (1250) of the plurality of memory dies 210A and 210B). The first memory die 210A and the second memory die 210B may perform a comparison operation (tCOMPARE) of the first training data TD1 and the first pattern data PD1 and the second pattern data PD2 based on a comparison operation instruction command 6Xh.

A DMA write operation 1260 may be performed to transfer the first training data TD1 to the third memory die 210C and the fourth memory die 210D at substantially the same timing in the storage controller 100. The storage controller 100 may transmit the first training data TD1 to the third memory die 210C and the fourth memory die 210D (i.e., DMA write operation (1260) of the plurality of memory dies 21C and 210D). At this time, the storage controller 100 may transmit a command SCE instructing the start of data transfer to the third memory die 210C and the fourth memory die 210D immediately before the DMA write operation 1260. The storage controller 100 may transmit a command SCT indicating termination of data transfer to the third memory die 210C and the fourth memory die 210D after the DMA write operation 1260.

The comparison operation (tCOMPARE) of the first memory die 210A and the second memory die 210B may be performed in parallel with the DMA write operation 1260 of the third memory die 210C and the fourth memory die 210D. While the comparison operation (tCOMPARE) of the first memory die 210A and the second memory die 210B is performed, the first training data TD1 may be transmitted to the third memory die 210C and the fourth memory die 210D through the data signal DQ line of the first channel CH1. The idle time of the data signal DQ line of the first channel CH1 may be reduced. By performing write training in a 4-chip interleaved manner, the write training operation time may be reduced.

At t5 to t6, the third memory die 210C and the fourth memory die 210D may perform a second command receiving operation 1270 that receives a second command C2 instructing a comparison operation at substantially the same timing. The storage controller 100 may sequentially transmit a logic unit number selection signal LUNSEL#10 for selecting a 3-2 logic unit number 432, a compare operation instruction command 6Xh, and a standby command 00h to the third memory die 210C and the fourth memory die 210D (second command receiving operation (1270) of the plurality of memory dies 210C and 210D). The third memory die 210C and the fourth memory die 210D may perform a comparison operation (tCOMPARE) of the first training data TD1 and the third pattern data PD3 and the fourth pattern data PD4 based on a comparison operation instruction command 6Xh.

A DMA write operation 1280 may be performed to transfer the first training data TD1 to the fifth memory die 210E and the sixth memory die 210F at substantially the same timing in the storage controller 100. The storage controller 100 may transmit the first training data TD1 to the fifth memory die 210E and the sixth memory die 210F (i.e., DMA write operation (1280) of the plurality of memory dies 210E and 210F). At this time, the storage controller 100 may transmit a command SCE instructing the start of data transfer to the fifth memory die 210E and the sixth memory die 210F immediately before the DMA write operation 1280. The storage controller 100 may transmit a command SCT indicating termination of data transfer to the fifth memory die 210E and the sixth memory die 210F after the DMA write operation 1280.

The first memory die 210A and the second memory die 210B may sequentially receive a status read command and perform a status read operation SR to transmit a pass/fail value PF in response to the status read command.

The first memory die 210A may receive a status read command and perform a status read operation SR 1290a that transmits a first pass/fail value PF1 in response to the status read command. The storage controller 100 may transmit a logic unit number selection signal LUNSEL#0 and a status read instruction command 70h to the first memory die 210A to select a logic unit number corresponding to the first memory die 210A as a status read operation SR 1290a. The first memory die 210A may transmit a status output command Status Output to the storage controller 100 in response to the status read instruction command 70h (i.e., the status read operation (SR) 1290a of the first memory die 210A).

The second memory die 210B may receive a status read command and perform a status read operation SR 1290b that transmits a second pass/fail value PF2 in response to the status read command. The storage controller 100 may transmit a logic unit number selection signal LUNSEL#1 and a status read instruction command 70h to the second memory die 210B to select a logic unit number corresponding to the second memory die 210B as a status read operation SR 1290b. The second memory die 210B may transmit a status output command Status Output to the storage controller 100 in response to the status read instruction command 70h (i.e., the status read operation (SR) 1290b of the second memory die 210B).

The state read operations SR 1290a and 1290b of the first and second memory dies 210A, 210B may be performed in parallel with the compare operation (tCOMPARE) of the third and fourth memory dies 210C, 210D.

While the compare operation (tCOMPARE) of the third and fourth memory dies 210C, 210D is performed, a status read command may be transmitted to the first and second memory dies 210A, 210B through the command/address signal CA line of the first channel CH1. The idle time of the command/address signal CA line of the first channel CH1 may be reduced. By performing write training in a 4-chip interleaved manner, the write training operation time may be reduced.

The compare operation (tCOMPARE) of the third and fourth memory dies 210C, 210D may be performed in parallel with the DMA write operation 1280 of the fifth memory die 210E and the sixth memory die 210F. While the comparison operation (tCOMPARE) of the third and fourth memory dies 210C, 210D is performed, the first training data TD1 may be transmitted to the fifth memory die 210E and the sixth memory die 210F through the data signal DQ line of the first channel CH1. The idle time of the data signal DQ line of the first channel CH1 may be reduced. By performing write training in a 4-chip interleaved manner, the write training operation time may be reduced.

At t6~t7, the first memory die 210A and the second memory die 210B may perform a first command receiving operation 1300 that receives a first command C1 instructing a program operation at substantially the same timing. A storage controller 100 of FIG. 1 may sequentially transmit a logic unit number selection signal LUNSEL#9 for selecting a 3-1 logic unit number 431 of FIG. 4, a program instruction command 63h, and a standby command 00h to a plurality of memory dies 210A, 210B (i.e., a first command receiving operation (1300) of the first memory die 210A and the second memory die 210B).

The fifth memory die 210E and the sixth memory die 210F may perform a second command receiving operation 1310 that receives a second command C2 instructing a comparison operation at substantially the same timing. The storage controller 100 may sequentially transmit a logic unit number selection signal LUNSEL#11 for selecting a 3-3 logic unit number 433, a compare operation instruction command 6Xh, and a standby command 00h to the fifth memory die 210E and the sixth memory die 210F (second command receiving operation (1310) of the plurality of memory dies 210E and 210F). The fifth memory die 210E and the sixth memory die 210F may perform a comparison operation (tCOMPARE) of the first training data TD1 and the fifth pattern data PD5 and the sixth pattern data PD6 based on a comparison operation instruction command 6Xh.

A DMA write operation 1320 may be performed to transfer the first training data TD1 to the seventh memory die 210G and the eighth memory die 210H at substantially the same timing in the storage controller 100. The storage controller 100 may transmit the first training data TD1 to the seventh memory die 210G and the eighth memory die 210H (i.e., DMA write operation (1320) of the plurality of memory dies 210G and 210H). At this time, the storage controller 100 may transmit a command SCE instructing the start of data transfer to the seventh memory die 210G and the eighth memory die 210H immediately before the DMA write operation 1320. The storage controller 100 may transmit a command SCT indicating termination of data transfer to the seventh memory die 210G and the eighth memory die 210H after the DMA write operation 1320.

The third memory die 210C and the fourth memory die 210D may sequentially receive a status read command and perform a status read operation SR to transmit a pass/fail value PF in response to the status read command.

The third memory die 210C may receive a status read command and perform a status read operation SR 1290c that transmits a third pass/fail value PF3 in response to the status read command. The storage controller 100 may transmit a logic unit number selection signal LUNSEL#2 and a status read instruction command 70h to the third memory die 210C to select a logic unit number corresponding to the third memory die 210C as a status read operation SR 1290c. The third memory die 210C may transmit a status output command Status Output to the storage controller 100 in response to the status read instruction command 70h (i.e., the status read operation (SR) 1290c of the third memory die 210C).

The fourth memory die 210D may receive a status read command and perform a status read operation SR 1290d that transmits a fourth pass/fail value PF4 in response to the status read command. The storage controller 100 may transmit a logic unit number selection signal LUNSEL#3 and a status read instruction command 70h to the fourth memory die 210D to select a logic unit number corresponding to the fourth memory die 210D as a status read operation SR 1290d. The fourth memory die 210D may transmit a status output command Status Output to the storage controller 100 in response to the status read instruction command 70h (i.e., the status read operation (SR) 1290d of the fourth memory die 210D).

At t7~t8, the third memory die 210C and the fourth memory die 210D may perform a first command receiving operation 1330 that receives a first command C1 instructing a program operation at substantially the same timing. The storage controller 100 may sequentially transmit a logic unit number selection signal LUNSEL#10 for selecting a 3-3 logic unit number 433 in FIG. 4, a program instruction command 63h, and a standby command 00h to a plurality of memory dies 210C, 210D (i.e., a first command receiving operation (1330) of the 3rd memory die 210C and the 4th memory die 210D).

The seventh memory die 210G and the eighth memory die 210H may perform a second command receiving operation 1340 that receives a second command C2 instructing a comparison operation at substantially the same timing. The storage controller 100 may sequentially transmit a logic unit number selection signal LUNSEL#12 for selecting a 3rd-4th logic unit number 434, a compare operation instruction command 6Xh, and a standby command 00h to the 7th memory die 210G and the 8th memory die 210H (second command receiving operation (1340) of the plurality of memory dies 210G and 210H). The seventh memory die 210G and the eighth memory die 210H may perform a comparison operation (tCOMPARE) of the first training data TD1 and the seventh pattern data PD7 and the eighth pattern data PD8 based on a comparison operation instruction command 6Xh.

A DMA write operation 1350 may be performed in the storage controller 100 to transfer first training data TD1 to the first memory die 210A and the second memory die 210B at substantially the same timing. The storage controller 100 may transmit first training data TD1 to the first memory die 210A and the second memory die 210B (i.e., DMA write operation (1350) of the plurality of memory dies 210A and 210B). At this time, the storage controller 100 may transmit a command SCE instructing the start of data transfer to the first memory die 210A and the second memory die 210B immediately before the DMA write operation 1350. The storage controller 100 may transmit a command SCT indicating termination of data transfer to the first memory die 210A and the second memory die 210B after the DMA write operation 1350.

The fifth memory die 210E and the sixth memory die 210F may sequentially receive a status read command and perform a status read operation SR to transmit a pass/fail value PF in response to the status read command.

The fifth memory die 210E may receive a status read command and perform a status read operation SR 1290e that transmits a fifth pass/fail value PF5 in response to the status read command. The storage controller 100 may transmit a logic unit number selection signal LUNSEL#4 and a status read instruction command 70h to the fifth memory die 210E to select a logic unit number corresponding to the fifth memory die 210E as a status read operation SR 1290e. The fifth memory die 210E may transmit a status output command Status Output to the storage controller 100 in response to the status read instruction command 70h (i.e., the status read operation (SR) 1290e of the fifth memory die 210E).

The sixth memory die 210F may receive a status read command and perform a status read operation SR 1290f that transmits a sixth pass/fail value PF6 in response to the status read command. The storage controller 100 may transmit a logic unit number selection signal LUNSEL#5 and a status read instruction command 70h to the sixth memory die 210F to select a logic unit number corresponding to the sixth memory die 210F as a status read operation SR 1290f. The sixth memory die 210F may transmit a status output command Status Output to the storage controller 100 in response to the status read instruction command 70h (i.e., the status read operation (SR) 1290f of the sixth memory die 210F).

At t8~t9, the fifth memory die 210E and the sixth memory die 210F may perform a first command receiving operation 1360 that receives a first command C1 instructing a program operation at substantially the same timing. The storage controller 100 may sequentially transmit a logic unit number selection signal LUNSEL#11 for selecting the 3-3 logic unit number 433 in FIG. 4, a program instruction command 63h, and a standby command 00h to a plurality of memory dies 210E, 210F (i.e., a first command receiving operation (1360) of the 5th memory die 210E and the 6th memory die 210F).

The first memory die 210A and the second memory die 210B may perform a second command receiving operation 1370 that receives a second command C2 instructing a comparison operation at substantially the same timing. The storage controller 100 may sequentially transmit a logic unit number selection signal LUNSEL#9 for selecting a 3-1 logic unit number 431, a compare operation instruction command 6Xh, and a standby command 00h to the first memory die 210A and the second memory die 210B (second command receiving operation (1370) of the plurality of memory dies 210A and 210B). The first memory die 210A and the second memory die 210B may perform a comparison operation (tCOMPARE) of the first training data TD1 and the first pattern data PD1 and the second pattern data PD2 based on a comparison operation instruction command 6Xh.

A DMA write operation 1380 may be performed to transfer the first training data TD1 to the third memory die 210C and the fourth memory die 210D at substantially the same timing in the storage controller 100. The storage controller 100 may transmit the first training data TD1 to the third memory die 210C and the fourth memory die 210D (i.e., DMA write operation (1380) of the plurality of memory dies 210C and 210D). At this time, the storage controller 100 may transmit a command SCE instructing the start of data transfer to the third memory die 210C and the fourth memory die 210D immediately before the DMA write operation 1380. The storage controller 100 may transmit a command SCT indicating termination of data transfer to the third memory die 210C and the fourth memory die 210D after the DMA write operation 1380.

The seventh memory die 210G and the eighth memory die 210H may sequentially receive a status read command and perform a status read operation SR to transmit a pass/fail value PF in response to the status read command.

The seventh memory die 210G may receive a status read command and perform a status read operation SR 1290g that transmits a seventh pass/fail value PF7 in response to the status read command. The storage controller 100 may transmit a logic unit number selection signal LUNSEL#6 and a state read instruction command 70h to the seventh memory die 210G to select a logic unit number corresponding to the seventh memory die 210G as a state read operation SR 1290g. The seventh memory die 210G may transmit a status output command Status Output to the storage controller 100 in response to the status read instruction command 70h (i.e., the status read operation (SR) 1290g of the seventh memory die 210G).

The eighth memory die 210H may receive a status read command and perform a status read operation SR 1290h that transmits an eighth pass/fail value PF8 in response to the status read command. The storage controller 100 may transmit a logic unit number selection signal LUNSEL#7 and a status read instruction command 70h for selecting a logic unit number corresponding to the eighth memory die 210H as a status read operation SR 1290h to the eighth memory die 210H. The eighth memory die 210H may transmit a status output command Status Output to the storage controller 100 in response to the status read instruction command 70h (i.e., the status read operation (SR) 1290h of the eighth memory die 210H).

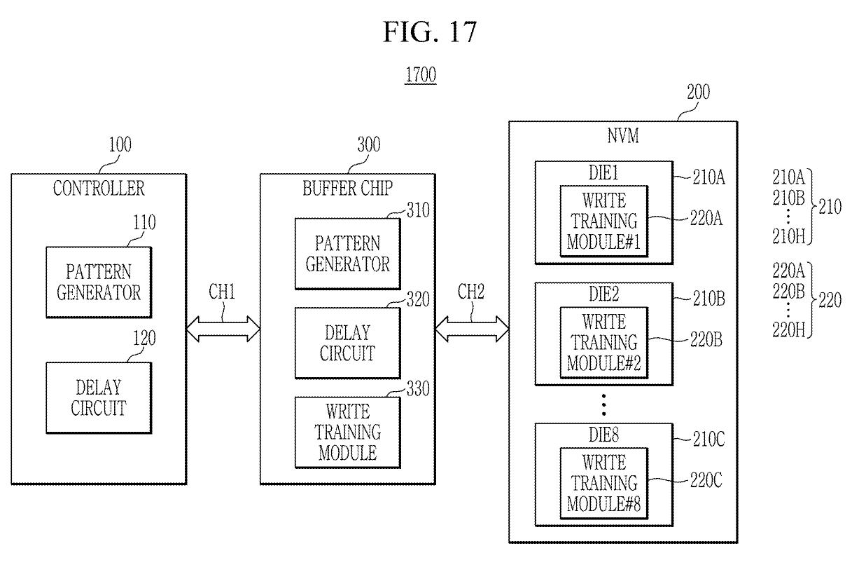

FIG. 17 is a block diagram of a storage device including a buffer chip according to an embodiment.

Referring to FIG. 17, a storage device 1700 may include a nonvolatile memory device 200, a storage controller 100, and a buffer chip 300. The storage device 1700 corresponds to a modified example of the storage device 10 of FIG. 1 and may further include a buffer chip 300 compared to the storage device 10. The contents of the storage controller 100 and the nonvolatile memory device 200 are the same as in FIG. 1.

A buffer chip 300 may be connected between a storage controller 100 and a nonvolatile memory device 200. The buffer chip 300 may communicate with the storage controller 100 through a first channel CH1, and the nonvolatile memory device 200 may communicate with the buffer chip 300 through a second channel CH2. The buffer chip 300 may also be referred to as a Frequency Boosting Interface FBI circuit. The buffer chip 300 and the nonvolatile memory device 200 may be implemented in a single package.

When the storage device 1700 includes a buffer chip 300, the write training operation may include a first write training operation between the storage controller 100 and the buffer chip 300 and a second write training operation between the buffer chip 300 and the nonvolatile memory device 200. The buffer chip 300 may be operated in delay mode or retiming mode. In the delay mode of the buffer chip 300, the storage controller 100 and the nonvolatile memory device 200 may transmit data, command, and address signals through the buffer chip 300. The first writing training operation and the second writing training operation may be performed similarly to the embodiments described above with reference to FIGS. 1 to 16.

In the retiming mode of the buffer chip 300, the buffer chip 300 may receive training data from the storage controller 100 and determine whether the training data passes or fails. The buffer chip 300 may generate pattern data having a training pattern and output the pattern data to a nonvolatile memory device 200.

The buffer chip 300 may include a write training module 330 that performs write training. In certain situations, such as booting or initialization, the write training module 330 may perform write training to determine whether training data received from the storage controller 100 is pass/fail.

The buffer chip 300 may include a pattern generator 310 and a delay circuit 320. The pattern generator 310 may generate pattern data having a training pattern for writing training. The delay circuit 320 may output a data strobe signal and pattern data synchronized to the data strobe signal as training data according to a specific delay value.

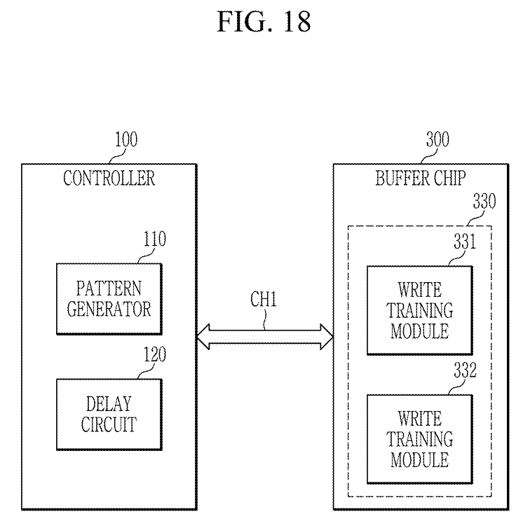

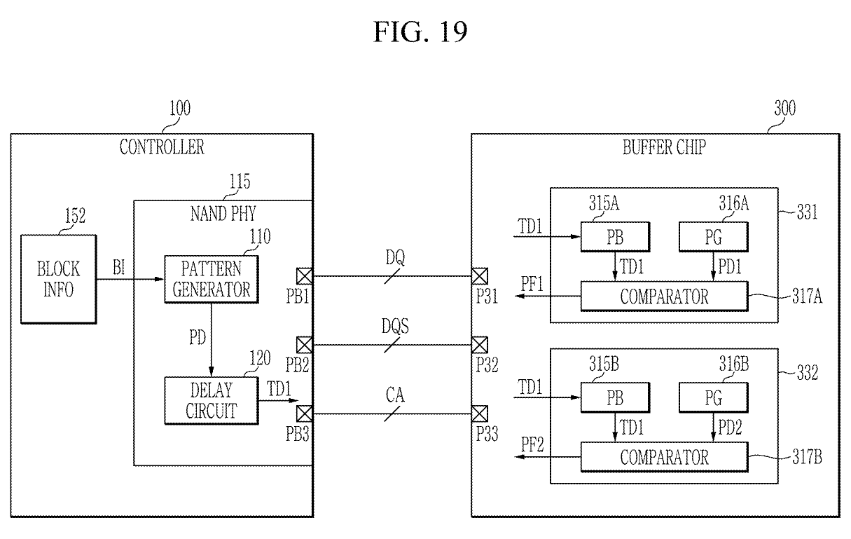

FIGS. 18 and 19 are block diagrams of a storage controller and buffer chip connected to a first channel according to an embodiment.

Referring to FIG. 18, the write training module 330 of the buffer chip 300 may include a first write training module 331 and a second write training module 332.

In certain situations, such as booting or initialization, the first write training module 331 and the second write training module 332 may perform write training to determine whether training data received from the storage controller 100 is pass/fail.

The first writing training module 331 and the second writing training module 332 may generate a pass/fail value by determining whether training data passes/fails. The first write training module 331 and the second write training module 332 may each transmit a pass/fail value to the storage controller 100.

The contents of the pattern generator 110 and delay circuit 120 included in the storage controller 100 are the same as in FIG. 1.

Referring to FIG. 19, the storage controller 100 and the buffer chip 300 may communicate in the SCA manner in which commands and addresses are transmitted separately from data. The buffer chip 300 may include a first write training module 331 and a second write training module 332. The buffer chip 300 may include a plurality of pins P31 to P33.

The buffer chip 300 may transmit and receive a data signal DQ to and from the storage controller 100 through the data pin P31. The buffer chip 300 may transmit and receive a data strobe signal DQS to and from the storage controller 100 through the data strobe pin P32. The buffer chip 300 may receive a command/address signal CA from the storage controller 100 through the command/address pin P33. The buffer chip 300 may further include a command/address clock pin configured to receive a command/address clock signal.

The storage controller 100 may include a plurality of pins PB1 to PB3 each connected to a plurality of pins P31 to P33 of the buffer chip 300. At this time, signal lines through which a data signal DQ, a data strobe signal DQS, and a command/address signal CA are transmitted may constitute a first channel CH1 in FIG. 1.

The storage controller 100 may include block information 152, a pattern generator 110, and a delay circuit 120. Block information 152 may include logic unit numbers BI corresponding to the plurality of write training modules 331, 332 of the buffer chip. The pattern generator 110 and delay circuit 120 may be included in the nonvolatile memory interface 115. The nonvolatile memory interface 115 may correspond to a NAND physical layer, i.e., a NAND PHY.

The pattern generator 110 may obtain a logic unit number BI corresponding to a plurality of write training modules 331, 332 of the buffer chip from the block information 152. A pattern generator 110 may generate pattern data PD having a training pattern based on a logic unit number BI. The delay circuit 120 may output a data strobe signal DQS and pattern data PD synchronized to the data strobe signal DQS as first training data TD1 according to a specific delay value.

The first write training module 331 may include a page buffer 315A, a pattern generator 316A, and a comparator 317A. The page buffer 315A may receive first training data TD1 from the storage controller 100. The page buffer 315A may store first training data TD1.

The pattern generator 316A may generate first pattern data PD1. The first pattern data PD1 may be identical to the pattern data PD generated by the pattern generator 110. A comparator 317A may generate a first pass/fail value PF1 indicating whether the first training data TD1 passes or fails by comparing the first training data TD1 with the first pattern data PD1.

The second write training module 332 may include a page buffer 315B, a pattern generator 316B, and a comparator 317B. The page buffer 315B may receive first training data TD1 from the storage controller 100. The page buffer 315B may store first training data TD1.

The pattern generator 316B may generate second pattern data PD2. The second pattern data PD2 may be identical to the pattern data PD generated by the pattern generator 110. A comparator 317B may generate a second pass/fail value PF2 indicating whether the first training data TD1 passes or fails by comparing the first training data TD1 with the second pattern data PD2.

The pattern generators 316A and 316B may be synchronized with the pattern generator 110 of the storage controller 100. For example, the same initial value, i.e., seed, may be input to the pattern generators 316A and 316B, and a polynomial representing the arrangement of taps used to generate the next state may be applied to the pattern generators (110, 316A, and 316B). Accordingly, the pattern data PD generated by the pattern generator 110 of the storage controller 100 may be identical to the first pattern data PD1 and the second pattern data PD2 generated by the pattern generators 316A and 316B, respectively.

FIGS. 20 and 21 are timing diagrams for buffer chip broadcasting according to an embodiment.

The write training operation may include a first transfer operation via a command/address signal CA line and a command/address pin P33, and a second transfer operation via a data signal DQ line and a data pin P31. By performing the first transmission operation for the first writing training module 331 and the second writing training module 332 in a broadcast manner, the idle time for the command/address signal CA lines may be reduced. By performing the second transmission operation for the first writing training module 331 and the second writing training module 332 in a broadcast manner, the idle time for the data signal DQ lines may be reduced.

Below, the specific operations of the first writing training module 331 and the second writing training module 332 will be described.

Referring to FIG. 20 and FIG. 21, at t0 to t1, the first writing training module 331 and the second writing training module 332 may perform a first command receiving operation 2000 that receives a first command C1 that instructs a program operation. The storage controller 100 of FIG. 19 may sequentially transmit a logic unit number selection signal LUNSEL#13 for selecting a fourth logic unit number 440, a program instruction command 63h, and a standby command 00h to the first write training module 331 and the second write training module 332 (i.e., the first command receiving operation (2000) of the first write training module 331 and the second write training module 332).

At t1~t2, the first writing training module 331 and the second writing training module 332 may complete preparation to receive the first training data TD1 after the data loading time (tADL) 2001.

At t2~t3, a DMA write operation 2002 may be performed to transfer the first training data TD1 of FIG. 19 from the storage controller 100 to the first write training module 331 and the second write training module 332. The storage controller 100 may transmit first training data TD1 to the first write training module 331 and the second write training module 332 (i.e., DMA write operation (2002) of the plurality of write training modules 331 and 332). At this time, the storage controller 100 may transmit a command SCE instructing the start of data transfer to the first write training module 331 and the second write training module 332 immediately before the DMA write operation 2002. The storage controller 100 may transmit a command SCT indicating termination of data transfer to the first write training module 331 and the second write training module 332 after the DMA write operation 2002.

At t3~t4, the first writing training module 331 and the second writing training module 332 may perform a second command receiving operation 2003 that receives a second command C2 that instructs a comparison operation. The storage controller 100 may sequentially transmit a logic unit number selection signal LUNSEL#13 for selecting a fourth logic unit number 440, a comparison operation instruction command 6Xh, and a standby command 00h to the first write training module 331 and the second write training module 332 (second command receiving operation (2003) of the plurality of write training modules 331 and 332). The first writing training module 331 and the second writing training module 332 may perform a comparison operation (tCOMPARE) 2004 of the first training data TD1 and the first pattern data PD1 and the second pattern data PD2 based on a comparison operation instruction command 6Xh.

At t4~t5, the first write training module 331 and the second write training module 332 may sequentially receive a state read command and perform a state read operation SR that transmits a pass/fail value PF in response to the state read command.

The first write training module 331 may receive a state read command and perform a state read operation SR 2005a that transmits a first pass/fail value PF1 in response to the state read command. The storage controller 100 may transmit a logic unit number selection signal LUNSEL#N and a state read instruction command 70h for selecting a logic unit number corresponding to the first write training module 331 as a state read operation SR 2005a to the first write training module 331. The first write training module 331 may transmit a status output command Status Output to the storage controller 100 in response to the status read instruction command 70h. At this time, the logic unit number corresponding to the first writing training module 331 may be any one of the logic unit numbers 421, 422 included in the second logic unit number 420.

The second write training module 332 may receive a state read command and perform a state read operation SR 2005b that transmits a second pass/fail value PF2 in response to the state read command. The storage controller 100 may transmit a logic unit number selection signal LUNSEL#M and a state read instruction command 70h for selecting a logic unit number corresponding to the second write training module 332 as a state read operation SR 2005b to the second write training module 332. The first write training module 332 may transmit a status output command Status Output to the storage controller 100 in response to the status read instruction command 70h. At this time, the logic unit number corresponding to the second writing training module 332 may be any one of the logic unit numbers (431, 432, 433, and 434) included in 3.

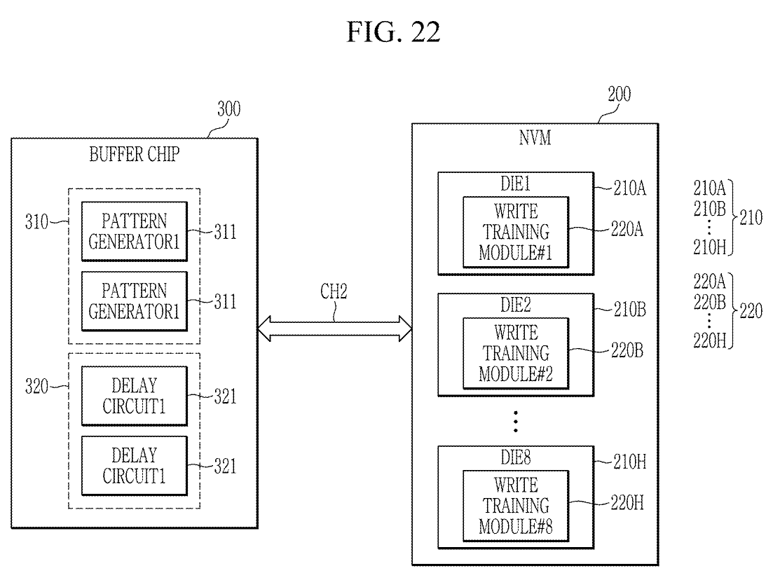

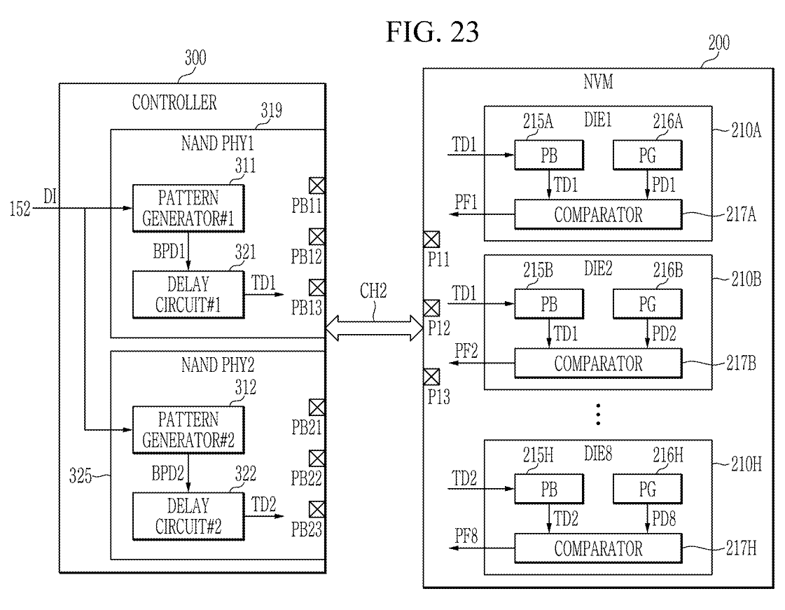

FIGS. 22 and 23 are block diagrams of a buffer chip and a nonvolatile memory device connected to a second channel according to an embodiment.

Referring to FIG. 22, the pattern generator 310 may include a first pattern generator 311 and a second pattern generator 312. The delay circuit 320 may include a first delay circuit 321 and a second delay circuit 322.

In certain situations, such as booting or initialization, the first pattern generator 311 may generate first buffer pattern data. The second pattern generator 312 may generate second pattern data.

The first delay circuit 321 may output a data strobe signal and first buffer pattern data BPD1 synchronized to the data strobe signal as first training data TD1 according to a specific delay value. The second delay circuit 322 may output a data strobe signal and second buffer pattern data BPD2 synchronized to the data strobe signal as second training data TD2 according to a specific delay value.

The contents of the first to eighth write training modules 220A to 220B included in the nonvolatile memory device 200 are the same as those in FIG. 1.

Referring to FIG. 23, the buffer chip 300 and the nonvolatile memory device 200 may communicate in the SCA manner in which commands and addresses are transmitted separately from data. The nonvolatile memory device 200 may include first to eighth memory dies 210A to 210H. A nonvolatile memory device 200 may include a plurality of pins P11 to P13.

The nonvolatile memory device 200 may transmit and receive a data signal DQ to and from the buffer chip 300 through the data pin P11. The nonvolatile memory device 200 may transmit and receive a data strobe signal DQS to and from the buffer chip 300 via the data strobe pin P12. The nonvolatile memory device 200 may receive a command/address signal CA from the buffer chip 300 through the command/address pin P13.

The buffer chip 300 may include a plurality of pins (PB11 to PB13, PB21 to PB23) each connected to a plurality of pins P11 to P13 of the nonvolatile memory device 200. At this time, signal lines through which data signals DQ, data strobe signals DQS and command/address signals CA are transmitted may form a second channel.

The first pattern generator 311 and the first delay circuit 321 may be included in the first non-volatile memory interface 319. The first non-volatile memory interface 319 may correspond to a NAND physical layer, i.e., a NAND PHY.

The second pattern generator 312 and the second delay circuit 322 may be included in the first non-volatile memory interface 325. The first non-volatile memory interface 325 may correspond to a NAND physical layer, i.e., a NAND PHY.

In certain situations, such as booting or initialization, a plurality of logic unit numbers DIs corresponding to the first memory die to the fourth memory die 210A to 210D may be obtained from the first pattern generator 311 block information 152 of FIG. 19. The first pattern generator 311 may generate first buffer pattern data BPD1 based on a plurality of logic unit numbers DI. The first pattern generator 311 may transmit the first buffer pattern data BPD1 to the first delay circuit 321. The first delay circuit 321 may output a data strobe signal and first buffer pattern data BPD1 synchronized to the data strobe signal as first training data TD1 according to a specific delay value. The first delay circuit 321 may transmit the first training data TD1 to the first memory die to the fourth memory die 210A to 210D.

In certain situations, such as booting or initialization, the second pattern generator 312 may obtain a plurality of logic unit numbers DIs corresponding to the fifth to eighth memory dies 210E to 210H from the block information 152.

The second pattern generator 312 may generate second buffer pattern data BPD2 based on a plurality of logic unit numbers DI. The second pattern generator 312 may transmit the second buffer pattern data BPD2 to the second delay circuit 322. The second delay circuit 322 may output a data strobe signal and second buffer pattern data BPD2 synchronized to the data strobe signal as second training data TD2 according to a specific delay value. The second delay circuit 322 may transmit the second training data TD2 to the fifth to eighth memory dies 210E to 210H.

The first memory die 210A may include a page buffer 215A, a pattern generator 216A, and a comparator 217A. The page buffer 215A may receive first training data TD1 from the buffer chip 300. The page buffer 215A may store first training data TD1. The pattern generator 216A may generate first pattern data PD1. The first pattern data PD1 may be identical to the buffer pattern data BPD generated by the first pattern generator 311. A comparator 217A may generate a first pass/fail value PF1 indicating whether the first training data TD1 passes or fails by comparing the first training data TD1 with the first buffer pattern data BPD1.

The second memory die 210B may include a page buffer 215B, a pattern generator 216B, and a comparator 217B. The page buffer 215B may receive first training data TD1 from the buffer chip 300. The page buffer 215B may store first training data TD1. The pattern generator 216B may generate second pattern data PD2. The second pattern data PD2 may be identical to the first buffer pattern data BPD1 generated by the first pattern generator 311. A comparator 217B may generate a second pass/fail value PF2 indicating whether the first training data TD1 passes or fails by comparing the first training data TD1 with the second pattern data PD2.

The third memory die and the fourth memory die 210C, 210D may also generate the third pass/fail value PF3 and the fourth pass/fail value PF4, respectively, through the same process as above.

The eighth memory die 210H may include a page buffer 215H, a pattern generator 216H, and a comparator 217H. The page buffer 215H may receive second training data TD2 from the buffer chip 300. The page buffer 215H may store second training data TD2. The pattern generator 216H may generate the eighth pattern data PD8. The 8th pattern data PD8 may be identical to the second buffer pattern data BPD2 generated by the second pattern generator 312. The comparator 217B may generate an eighth pass/fail value PF8 indicating whether the second training data TD2 passes or fails by comparing the second training data TD2 with the eighth pattern data PD8.

The fifth memory die and the seventh memory die 210E to 210G may also generate a fifth pass/fail value PF5, a sixth pass/fail value PF6, and a seventh pass/fail value PF7, respectively, through the same process as above.

The pattern generators 216A to 216H may be synchronized with the first pattern generator 311 and the second pattern generator 312. For example, the same initial value, i.e., seed, may be input to the pattern generators (311, 312, 216A to 216H), and a polynomial representing the arrangement of taps used to generate the next state may be applied to the pattern generators (311, 312, 216A to 216H). Accordingly, the first buffer pattern data BPD1 and the second buffer pattern data BPD2 generated from the first pattern generator 311 and the second pattern generator 312 of the buffer chip 300, respectively, may be identical to the first to eighth pattern data PD1 to PD8 generated from the pattern generators 216A to 216H, respectively.

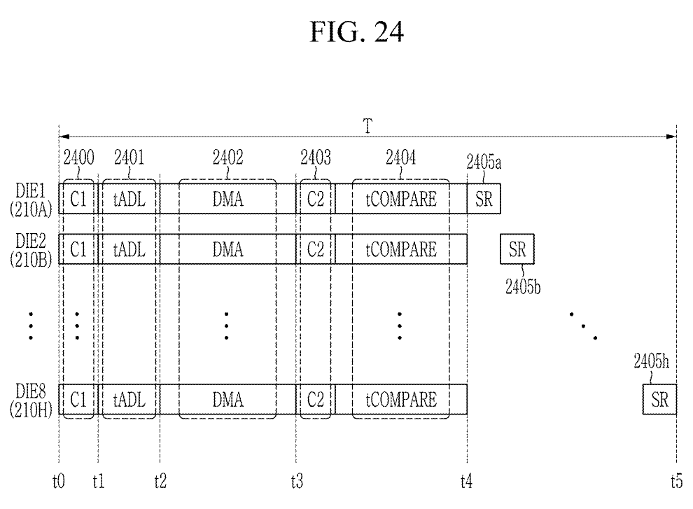

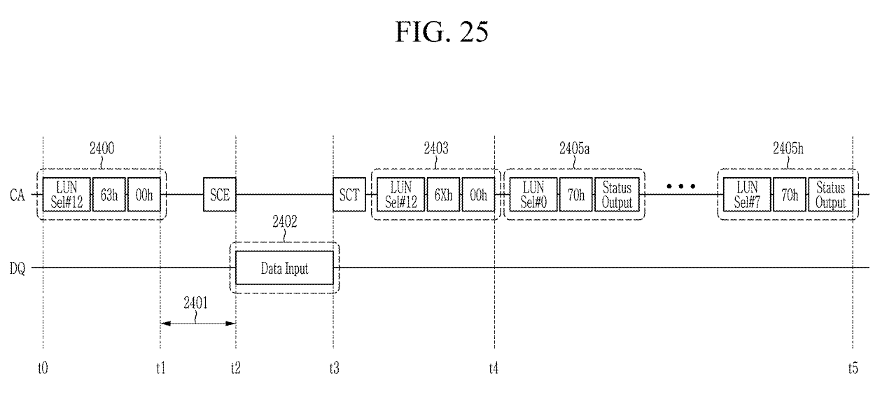

FIGS. 24 and 25 are broadcast timing diagrams of a memory die according to an embodiment.

The write training operation may include a first transfer operation via a command/address signal CA line and a command/address pin P13, and a second transfer operation via a data signal DQ line and a data pin P11. By performing the first transfer operation for the first to eighth memory dies 210A to 210H in a broadcast manner, the idle time for the command/address signal CA lines may be reduced. By performing the second transfer operation for the first to eighth memory dies 210A to 210H in a broadcast manner, the idle time for the data signal DQ lines may be reduced.

Below, the specific operations for the first to eighth memory dies 210A to 210H will be described.

Referring to FIGS. 24 and 25, at t0 to t1, a plurality of memory dies 210A to 210H may perform a first command receiving operation 2400 to receive a first command C1 instructing a program operation. A storage controller 100 of FIG. 1 may sequentially transmit a logic unit number selection signal LUNSEL#12 for selecting a first logic unit number 410 of FIG. 4, a program instruction command 63h, and a standby command 00h to a plurality of memory dies 210A to 210H (i.e., a first command receiving operation (2000) of the plurality of memory dies 210A to 210H).

At t1 to t2, the plurality of memory dies 210A to 210H may be ready to receive the first training data TD1 and the second training data TD2 through a data loading time (tADL) 2401.

At t2 to t3, a DMA write operation 2402 may be performed to transfer first training data TD1 and second training data TD2 from the buffer chip 300 to the plurality of memory dies 210A to 210H. For example, the first delay circuit 321 may transmit the first training data TD1 to the first memory die to the fourth memory die 210A to 210D. The second delay circuit 322 may transmit the second training data TD2 to the fifth to eighth memory dies 210E to 210H (i.e., DMA write operation (2402) of the plurality of memory dies 210A to 210H).

The buffer chip 300 may transmit a command SCE indicating the start of data transfer to the plurality of memory dies 210A to 210H immediately before a DMA write operation 2402. The buffer chip 300 may transmit a command SCT indicating termination of data transfer to the plurality of memory dies 210A to 210H after a DMA write operation 2402.

At t3 to t4, the plurality of memory dies 210A to 210H may perform a second command receiving operation 2403 that receives a second command C2 instructing a compare operation. The buffer chip 300 may sequentially transmit a logic unit number selection signal LUNSEL#12 for selecting a first logic unit number 410, a compare operation instruction command 6Xh, and a standby command 00h to a plurality of memory dies 210A to 210H (i.e., a second command receiving operation (2403) of the plurality of memory dies 210A to 210H). A plurality of memory dies 210A to 210D may perform a comparison operation (tCOMPARE) 2404 between first training data TD1 and pattern data PD1 to PD4 based on a comparison operation instruction command 6Xh. A plurality of memory dies 210E to 210H may perform a comparison operation (tCOMPARE) 2404 between second training data TD2 and pattern data PD4 to PD8 based on a comparison operation instruction command 6Xh.

At t4 to t5, the first to eighth memory dies 210A to 210H may sequentially receive a status read command and perform a status read operation SR that transmits a pass/fail value PF in response to the status read command.

The first memory die 210A may receive a status read command and perform a status read operation SR 2405a that transmits a first pass/fail value PF1 in response to the status read command. The buffer chip 300 may transmit a logic unit number selection signal LUNSEL#0 for selecting a logic unit number corresponding to the first memory die 210A and a status read instruction command 70h to the first memory die 210A. The first memory die 210A may transmit a status output command Status Output to the storage controller 100 in response to the status read instruction command 70h. (i.e., the status read operation (SR) 2405a of the memory die 210A).

The eighth memory die 210H may receive a status read command and perform a status read operation SR 2405h that transmits an eighth pass/fail value PF8 in response to the status read command. The buffer chip 300 may transmit a logic unit number selection signal LUNSEL#7 for selecting a logic unit number corresponding to the eighth memory die 210H and a status read instruction command 70h to the eighth memory die 210H. The eighth memory die 210H may transmit a status output command Status Output to the storage controller 100 in response to the status read instruction command 70h (i.e., the status read operation (SR) 2405h of the eighth memory die 210H).

The status read operations SR 2405b to 2405g of the second to seventh memory dies 210B to 210G are also identical to the descriptions of the status read operations SR 2405a of the first memory die 210A and the eighth memory die 210H 2405h.

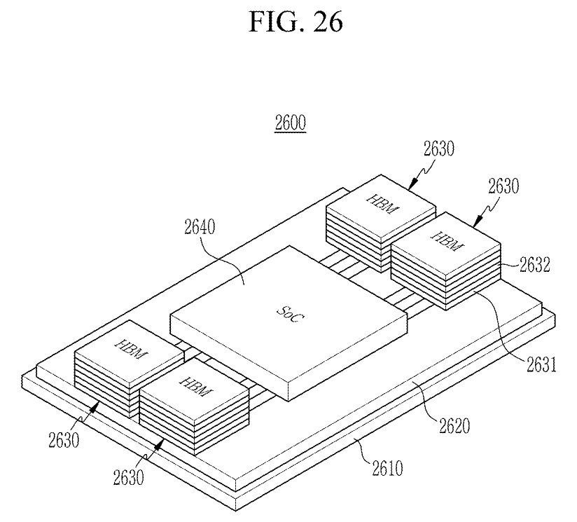

FIG. 26 is a diagram for explaining a memory system according to an embodiment of the present disclosure.

Referring to FIG. 26, a semiconductor package 2600 may be a memory module including at least one stack semiconductor chip 2630 and a system-on-chip SOC 2640 mounted on a package substrate 2610, such as a printed circuit board. An interposer 2620 may optionally be further provided on the package substrate 2610. The stack semiconductor chip 2630 may be formed as a chip-on-chip CoC. A stack semiconductor chip 2630 may include at least one memory chip 2632 stacked on a buffer chip 2631, such as a logic chip. The buffer chip 2631 and at least one memory chip 2632 may be connected to each other by a through silicon via TSV. The buffer chip 2631 may perform a training operation for the memory chip 2632, and the training operation method of the buffer chip 2631 may be applied to the embodiments described in FIGS. 1 to 24. The stack semiconductor chip 2630 may be, for example, a high bandwidth memory HBM of 500 GB/sec to 1 TB/sec or more.

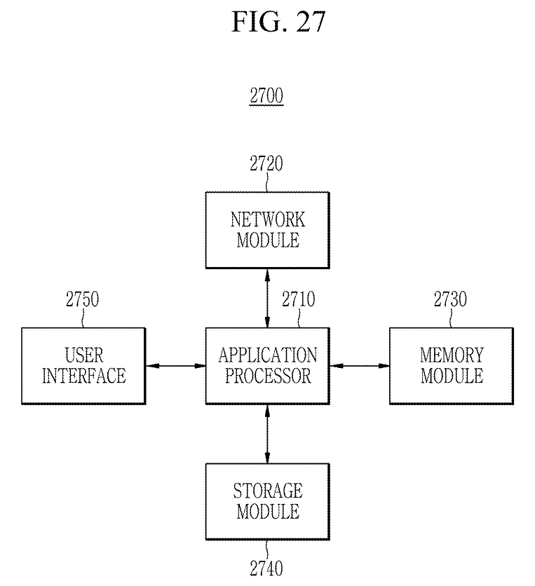

FIG. 27 is a block diagram exemplarily showing a mobile system to which a memory system according to an embodiment of the present disclosure is applied.

Referring to FIG. 27, the mobile system 2700 may include an application processor (2710; APPLICATION PROCESSOR), a network module (2720; NETWORK MODULE), a memory module (2730; MEMORY MODULE), a storage module (2740; STORAGE MODULE), and a user interface (2750; USER INTERFACE).

The network module 2720 may communicate with external devices. For example, the network module 2720 may support wireless communications such as CDMA (Code Division Multiple Access), GSM (Global System for Mobile communication), WCDMA (wideband CDMA), CDMA-2000, TDMA (Time Division Multiple Access), LTE (Long Term Evolution), WiMax, WLAN, UWB, Bluetooth, WI-DI, etc.

The memory module 2730 may function as main memory, operating memory, buffer memory, or cache memory of the mobile system 2700. The memory module 2730 may include volatile random access memory such as DRAM, SDRAM, DDR SDRAM, DDR2 SDRAM, DDR3 SDRAM, LPDDR SDARM, LPDDR3, SDRAM, LPDDR3 SDRAM, or nonvolatile random access memory such as PRAM, ReRAM, MRAM, FRAM, etc.

The storage module 2740 may store data. For example, the storage module 2740 may store data received from outside. The storage module 2740 may transmit data stored in the storage module 2740 to the application processor 2710. For example, the storage module 2740 may be implemented with a nonvolatile semiconductor memory device such as PRAM, MRAM, RRAM, NAND flash, NOR flash, or a three-dimensional structured NAND flash. For example, the storage module 2740 may be provided as a solid state drive SSD, a multimedia card MMC, an embedded multimedia card (eMMC), a universal flash storage UFS, etc.

In some embodiments, the storage module 2740 may include a memory controller, a buffer chip, and a memory device, as described in FIGS. 1 through 26. The storage module 2740 may perform timing training operations between the memory controller and the buffer chip, and between the buffer chip and the memory device, based on the control of the memory controller. Through timing training operations, the storage module 2740 may provide improved SI. Specific details regarding the training movements are the same as those described with reference to FIGS. 1 to 26, and are therefore omitted below.

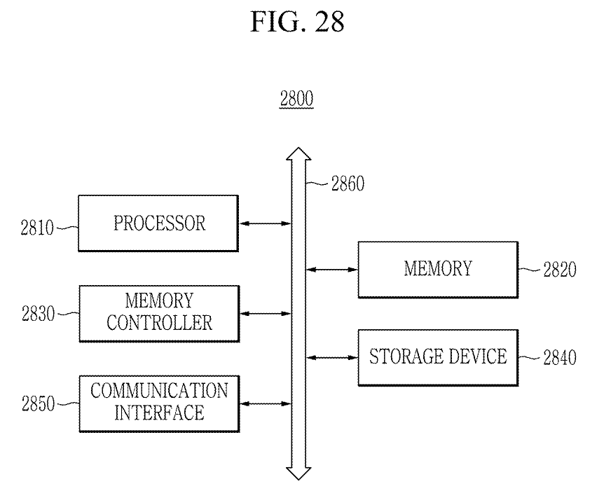

FIG. 28 is an example block diagram illustrating a computer device according to an embodiment.

Referring to FIG. 28, a computing device 2800 may include a processor 2810; Processor, a memory 2820; MEMORY, a memory controller (2830; MEMORY CONTROLLER), a storage device (2840; STORAGE DEVICE), a communication interface (2850; COMMUNICATION INTERFACE), and a bus 2860. The computing device 2800 may further include other general-purpose components.

The processor 2810 may control the overall operation of each component of the computing device 2800. The processor 2810 may be implemented as at least one of various processing units such as a CPU, an AP, and a GPU.

Memory 2820 may store various data and commands. A memory controller 2830 may control the transfer of data or commands to and from memory 2820. In some embodiments, the memory controller 2830 may be provided as a separate chip from the processor 2810. In some embodiments, the memory controller 2830 may be provided as an internal component of the processor 2810.

The storage device 2840 non-temporarily stores programs and data. In some embodiments, the storage device 2840 may include a memory controller, a buffer chip, and a memory device, as described in FIGS. 1 through 27. The storage device 2840 may perform timing training operations between the memory controller and the buffer chip, and between the buffer chip and the memory device, based on the control of the memory controller. Through timing training operations, the storage device 2840 may provide improved SI. Specific details regarding the training movements are the same as those described with reference to FIGS. 1 to 27, and are therefore omitted below.

The communication interface 2850 may support wired and wireless Internet communication of the computing device 2800. The communication interface 2850 may support various communication methods other than Internet communication.

The bus 2860 may provide communication capabilities between components of the computing device 2800. The bus 2860 may include at least one type of bus depending on the communication protocol between the components.

Although the embodiments of the present disclosure have been described in detail above, the scope of the present disclosure is not limited thereto, and various modifications and improvements made by those skilled in the art using the basic concept of the present disclosure defined in the following claims also fall within the scope of the present disclosure.

What is claimed is:

1. A nonvolatile memory device comprising:
a plurality of memory dies configured to perform write training based on training data received through a first channel and perform data input/output through the first channel;
a first memory die among the plurality of memory dies comprising:
a first pattern generator for generating first pattern data,
a first comparator for comparing the training data with the first pattern data to generate a first pass/fail value for the training data,
a first input/output circuit connected to the first channel and including a first termination resistor, and
a first control logic for generating a first enable signal for instructing turning on the first termination resistor during the write training and data input/output; and
a second memory die among the plurality of memory dies comprising:
a second pattern generator for generating second pattern data,
a second comparator for comparing the training data with the second pattern data to generate a second pass/fail value for the training data,
a second input/output circuit connected to the first channel and including a second termination resistor, and
a second control logic for generating a second enable signal for instructing turning off the second termination resistor during the write training and the data input/output.

2. The nonvolatile memory device of claim 1, wherein
the first memory die is connected to an end of the first channel.

3. The nonvolatile memory device of claim 2, wherein
the first memory die further includes a first page buffer for storing the training data, and
the second memory die further includes a second page buffer for storing the training data.

4. The nonvolatile memory device of claim 3, wherein
the first input/output circuit and the second input/output circuit configured to receive a first command instructing a program operation at substantially the same timing, transmit the first command to the first control logic and the second control logic, receive the training data at substantially the same timing, and transmit the training data to the first page buffer and the second page buffer, respectively.

5. The nonvolatile memory device of claim 4, wherein
the first input/output circuit and the second input/output circuit are further configured to receive a second command instructing a comparison operation at substantially the same timing, transmit the second command to the first control logic and the second control logic,
the first control logic configured to transmit a first-first enable signal to the first pattern generator and a second-1 enable signal to the first comparator in response to the second command,
the second control logic configured to transmit a first-second enable signal to the second pattern generator and a second-second enable signal to the second comparator in response to the second command,
the first pattern generator configured to generate the first pattern data based on the first-first enable signal and transmit the first pattern data to the first comparator,
the second pattern generator configured to generate the second pattern data based on the first-second enable signal and transmit the second pattern data to the second comparator,
the first comparator configured to compare the first pattern data with the training data and generate the first pass/fail value, and
the second comparator configured to compare the second pattern data with the training data and generate the second pass/fail value.

6. The nonvolatile memory device of claim 5, wherein
the first input/output circuit and the second input/output circuit are further configured to receive a third command requesting a pass/fail value at substantially the same timing, and transmit the third command to the first control logic and the second control logic,
the first control logic is further configured to control the first comparator to generate the first pass/fail value based on the third command, and
the second control logic is further configured to control the second comparator to generate the second pass/fail value based on the third command.

7. The nonvolatile memory device of claim 6, wherein
the plurality of memory dies are divided into a first group and a second group,
the first group and the second group each contain the same number of memory dies, and
input/output circuits of memory dies included in the first group are configured to receive the first command, the training data, the second command, and the third command earlier than input/output circuits of memory dies included in the second group.

8. The nonvolatile memory device of claim 6, wherein
the plurality of memory dies are divided into a first group, a second group, a third group, and a fourth group,
the first group, the second group, the third group, and the fourth group each include an equal number of memory dies,
input/output circuits of memory dies included in the first group are configured to receive the first command, the training data, the second command, and the third command earlier than input/output circuits of memory dies included in the second group,
input/output circuits of memory dies included in the second group are configured to receive the first command, the training data, the second command, and the third command earlier than input/output circuits of memory dies included in the third group, and
input/output circuits of memory dies included in the third group are configured to receive the first command, the training data, the second command, and the third command earlier than input/output circuits of memory dies included in the fourth group.

9. A storage device comprising:
a storage controller configured to output training data, a first logic unit number instructing buffer chip broadcasting
a buffer chip comprising a first write training module configured to:
generate first pattern data,
receive the training data through a first channel based on the first logic unit number,
compare the training data with the first pattern data, and
generate a first pass/fail value for the training data; and
a second write training module configured to:
generate second pattern data,
receive the training data through the first channel based on the first logic unit number, compare the training data with the second pattern data, and
generate a second pass/fail value for the training data.

10. The storage device of claim 9, wherein
the first writing training module and the second writing training module are further configured to receive a first command instructing a program operation from the controller at substantially the same timing, and receive the training data at substantially the same timing.

11. The storage device of claim 10, wherein
the first writing training module and the second writing training module are further configured to receive a second command instructing a comparison operation at substantially the same timing,
the first writing training module is further configured to generate the first pattern data based on the second command and compare the first pattern data with the training data to generate the first pass/fail value, and
the second writing training module is further configured to generate the second pattern data based on the second command and compare the second pattern data with the training data to generate the second pass/fail value.

12. The storage device of claim 11, wherein
the first writing training module and the second writing training module are further configured to receive a third command requesting a pass/fail value at substantially the same timing,
the first write training module is further configured to transmit the first pass/fail value to the storage controller based on the third command, and
the second write training module is further configured to transmit the second pass/fail value to the storage controller based on the third command.

13. The storage device of claim 9, wherein
the buffer chip further comprises:
a first delay circuit configured to delay the first pattern data according to a delay value and output the first training data; and
a second delay circuit configured to delay the second pattern data according to a delay value and output second training data.

14. The storage device of claim 13, wherein
a first group die including a plurality of memory dies configured to perform write training based on the first training data received through the second channel and perform data input/output through the second channel; and
a second group die including a plurality of memory dies configured to perform write training based on the second training data received through the second channel and perform data input/output through the second channel.

15. The storage device of claim 14, wherein
the first group die further comprises:
a third page buffer for obtaining the first training data through the second channel, a third pattern generator for generating third pattern data, a third comparator for comparing the first training data with the third pattern data to generate a third pass/fail value for the first training data, and a first input/output circuit connected to the second channel and transmitting and receiving commands, addresses, and data from the buffer chip, and
the second group die further comprises:
a fourth page buffer for obtaining the second training data through the second channel, a fourth pattern generator for generating fourth pattern data, a fourth comparator for comparing the second training data with the fourth pattern data to generate a fourth pass/fail value for the second training data, and a second input/output circuit connected to the second channel and transmitting and receiving commands, addresses, and data from the buffer chip.

16. The storage device of claim 15, wherein
the storage controller is further configured to output a second logic unit number for selecting a plurality of memory dies included in the first group die and the second group die,
the first input/output circuit and the second input/output circuit are further configured to receive the second logic unit number and the fourth command instructing program operation from the buffer chip at substantially the same timing, and
the third page buffer and the fourth page buffer are further configured to receive the first training data and the second training data at substantially the same timing.

17. The storage device of claim 16, wherein
the plurality of memory dies are further configured to receive a fifth command instructing a comparison operation from the buffer chip at substantially the same timing,
the third pattern generator is further configured to transmit the third pattern data to the third comparator based on the fifth command,
the fourth pattern generator is further configured to transmit the fourth pattern data to the fourth comparator based on the fifth command,
the third comparator is further configured to compare the third pattern data with the first training data to generate the third pass/fail value, and
the fourth comparator is further configured compare the fourth pattern data with the first training data to generate the fourth pass/fail value.

18. The storage device of claim 17, wherein
the plurality of memory dies are further configured to receive a sixth command requesting a pass/fail value from the buffer chip at substantially the same timing, and
the first input/output circuit and the second input/output circuit are further configured to transmit the third pass/fail value and the fourth pass/fail value to the buffer chip at substantially the same timing based on the sixth command.

19. The storage device of claim 14, wherein
among the plurality of memory dies included in the first group die and the plurality of memory dies included in the second group die, a first memory die includes a first termination resistor, a first input/output circuit including the first termination resistor, and a first control logic configured to generate a first odt signal determining an on state of the first termination resistor, and
among the plurality of memory dies included in the first group die and the plurality of memory dies included in the second group die, each of the memory dies excluding the first memory die includes a second termination resistor, a second input/output circuit including the second termination resistor, and a second control logic configured to generates a second odt signal that determines turning off the second termination resistor.

20. A storage device comprising:
a storage controller including a memory including:
a first logic unit number instructing buffer chip broadcasting,
a second logic unit number instructing a plurality of memory dies included in a group die,
a pattern generator configured to generate pattern data, and
a delay circuit configured to delay the pattern data according to a delay value and outputting training data;
a buffer chip configured to:
receive an address corresponding to the first logic unit number, an address corresponding to the second logic unit number, and the training data at substantially the same timing from the storage controller through a first channel,
generate first pattern data, and delay the first pattern data according to a delay value, and
output first training data; and
a nonvolatile memory configured to:
receive an address corresponding to the second logic unit number and the first training data from the buffer chip through a second channel at substantially the same timing, and
generate a pass/fail value based on the first training data.
